(19) United States
(12) Patent Application Publication
(10) Pub. No.: US 2025/0180608 A1
(43) Pub. Date: Jun. 5, 2025

(54) MAGNETIC SENSOR AND CURRENT SENSOR

(71) Applicant: Asahi Kasei Microdevices Corporation, Tokyo (JP)

(72) Inventors: Masato INOUE, Tokyo (JP); Saki USHIDA, Tokyo (JP)

(21) Appl. No.: 18/961,493

(22) Filed: Nov. 27, 2024

(30) Foreign Application Priority Data
Nov. 30, 2023 (JP) 2023-202367
Nov. 27, 2024 (JP) 2024-205915

(51) Int. Cl. G01R 15/20; G01R 19/00

(52) U.S. Cl. CPC G01R 15/205; G01R 19/0092

(57) ABSTRACT

A magnetic sensor 60 includes a substrate 61 installed on a conductor 24, where a plurality of blocks including first blocks 62a, 63a and second blocks 62b, 63b positioned near and far from the center of the conductor, respectively, relative to each other are arranged on one surface of the substrate, and a plurality of magnetoresistance elements 51 disposed on the substrate, wherein a part of the plurality of magnetoresistance elements is disposed in the first block and another part is disposed in the second block, and the first and second blocks include first subblock 62a₁, 63a₁, 62b₁, 63b₁, respectively, on which the magnetoresistance elements 51 having magnetic sensing directions that are directions identical to each other, and the magnetoresistance elements in the first subblocks 62a₁, 63a₁, 62b₁, 63b₁ of the first and second blocks 62a, 63a, 62b, 63b are connected in series to form the resistor side R1.

The contents of the following patent application(s) are incorporated herein by reference:
NO. 2023-202367 filed in JP on Nov. 30, 2023.
NO. 2024-205915 filed in JP on Nov. 27, 2024

### BACKGROUND

### 1. Technical Field

The present invention relates to a magnetic sensor and a current sensor.

### 2. Related Art

A dual linear (two linear) current sensor having two linear regions with different sensitivities enables, for example, measuring a current in a range equal to or less than the detection limit with high resolution in a normal situation and measuring a current in a range exceeding the detection limit with low resolution during a failure. In Patent Documents 1 and 2, the dual linear current sensor is configured with an amplifier having an amplification factor that is variable based on the output voltage of a current detector. However, since it needs the amplifier, the chip area in which the sensor is formed increases. In addition, in Patent Document 3, the dual linear current sensor is configured by serially connecting a magnetoresistance element that reaches magnetic saturation at a high sensitivity and a magnetoresistance element that does not reach magnetic saturation at a low sensitivity. However, the process for forming two types of magnetoresistance elements with different structures on the same chip is complex. Patent Document 1: Japanese Patent Application Publication No. 2010-197065
Patent document 2: U.S. Pat. No. 9,523,742 Specification
Patent Document 3: Specification of U.S. Patent Application Publication No. 2019/279804

### GENERAL DISCLOSURE

In a first aspect of the present invention, a magnetic sensor is provided, comprising: a substrate installed on a conductor, where a plurality of blocks including a first block and a second block positioned near and far from a center line of the conductor, respectively, relative to each other in a plan view are arranged on one surface; a plurality of magnetoresistance elements disposed on the substrate, wherein a part of the plurality of magnetoresistance elements is disposed in the first block and another part is disposed in the second block, wherein each of the first block and the second block includes a first subblock in which magnetoresistance elements having magnetic sensing directions that are directions identical to each other are disposed, and a magnetoresistance element in the first subblock of the first block and a magnetoresistance element in the first subblock of the second block are connected in series to form a first resistor side.

In a second aspect of the present invention, a current sensor is provided, including the conductor, the magnetic sensor of the first aspect, and a package sealing the conductor and the magnetic sensor.

Note that the summary clause does not necessarily describe all necessary features of the embodiments of the present invention. The present invention may also be a sub-combination of the features described above.

### BRIEF DESCRIPTION OF THE DRAWINGS

FIG. 1A illustrates an internal configuration of a current sensor according to the present embodiment in a top view.

FIG. 1B illustrates the internal configuration of the current sensors according to the present embodiment in a side view.

FIG. 2A illustrates an example of the arrangement and substrate layout of a full bridge magnetic sensor for detecting the horizontal magnetic field.

FIG. 2B illustrates the configuration of a magnetoresistance element in a side view.

FIG. 3 illustrates the circuit configuration of the full bridge magnetic sensors (two magneto-electric conversion units) and the magnetic field detection directions of the magnetoresistance elements.

FIG. 4 illustrates the magnetoresistance change of the magnetoresistance element within first and second blocks and the entire sensor with respect to the energization amount of a conductor.

FIG. 5A illustrates an example of the arrangement and substrate layout of half-bridge magnetic sensors for detecting the horizontal magnetic field.

FIG. 5B illustrates the circuit configuration of half-bridge magnetic sensors (two magneto-electric conversion units) and the magnetic field detection directions of the magnetoresistance elements.

FIG. 6A illustrates a first example of the arrangement of the first block and the second block.

FIG. 6B illustrates a second example of the arrangement of the first block and the second block.

FIG. 6C illustrates a third example of the arrangement of the first block and the second block.

FIG. 6D illustrates a fourth example of the arrangement of the first block and the second block.

FIG. 7A illustrates a block arrangement of the magnetoresistance elements constituting a quadruple linear current sensor, in which the sensitivity decreases as the energization amount increases, using a full bridge magnetic sensor.

FIG. 7B illustrates a block arrangement of the magnetoresistance elements constituting a quadruple linear current sensor, in which the sensitivity decreases as the energization amount increases, using a half-bridge magnetic sensor.

FIG. 7C illustrates the magnetoresistance changes of the magnetoresistance elements in the four blocks and each resistor side in FIG. 7A and FIG. 7B with respect to the energization amount of the conductor.

FIG. 8A illustrates the block arrangement of the magnetoresistance elements constituting the current sensor of dual linearity, in which the threshold of the overcurrent detection changes according to the energization amount, using the full bridge magnetic sensor.

FIG. 8B illustrates the block arrangement of the magnetoresistance elements constituting the current sensor of dual linearity, in which the threshold of the overcurrent detection changes according to the energization amount, using the half-bridge magnetic sensor.

FIG. 8C illustrates the magnetoresistance changes of the magnetoresistance elements in the four blocks and each resistor side in FIG. 8A and FIG. 8B with respect to the energization amount of the conductor.

FIG. 9A illustrates the block arrangement of the magnetoresistance elements constituting a current sensor of multi-linearity, in which the sensitivity changes according to the degree of the overcurrent, by using the full bridge magnetic sensor.

FIG. 9B illustrates the block arrangement of the magnetoresistance element constituting a current sensor of multi-linearity, in which the sensitivity changes according to the degree of the overcurrent, by using the half-bridge magnetic sensor.

FIG. 9C illustrates the magnetoresistance changes of the magnetoresistance elements in the two blocks and each resistor side in FIG. 9A and FIG. 9B with respect to the energization amount of the conductor.

FIG. 10A illustrates the behavior of the magnetoresistance changes of the magnetoresistance element in one block or subblock with respect to the magnetization.

FIG. 10B illustrates a general expression of the magnetoresistance change of each resistor side.

FIG. 11 illustrates four aspects (that is, (1) logarithmic increase, (2) exponential increase, (3) monotonic increase, and (4) arbitrary increase) of the change of the output voltage (that is, the magnetoresistance change of the magnetic sensor) of the current sensor with respect to the energization amount.

FIG. 12 illustrates the polarity ((a) unipolar, (b) bipolar symmetry, and (c) bipolar asymmetry) of the output voltage (that is, the magnetoresistance change of the magnetic sensor) of the current sensor with respect to the energization amount.

FIG. 13 illustrates an example of a combination of the aspect of the change in the output voltage of the current sensor illustrated in FIG. 11 and the polarity illustrated in FIG. 12.

FIG. 14A illustrates an example of the block arrangement, the magnetic field detection direction, and the direction of the bias magnetic field of the magnetoresistance element having the basic property of a first type I_{±}.

FIG. 14B illustrates the property of the magnetoresistance change with respect to the energization amount exhibited by the magnetoresistance element in FIG. 14A.

FIG. 15A illustrates an example of the block arrangement, the magnetic field detection direction, and the direction of the bias magnetic field of the magnetoresistance element having the basic property of a second type II_{±}.

FIG. 15B illustrates the property of the magnetoresistance change with respect to the energization amount exhibited by the magnetoresistance element in FIG. 15A.

FIG. 16A illustrates an example of the block arrangement, the magnetic field detection direction, and the direction of the bias magnetic field of the magnetoresistance element having the basic property of a third type III_{±}.

FIG. 16B illustrates the property of the magnetoresistance change with respect to the energization amount exhibited by the magnetoresistance element in FIG. 16A.

FIG. 17A illustrates the type and block arrangement of the magnetoresistance element exhibiting the (b) bipolar symmetry and (1) logarithmic increase property.

FIG. 17B illustrates the property of the magnetoresistance change with respect to the energization amount exhibited by each block of the magnetoresistance elements and the sensor (each resistor side) in FIG. 17A.

FIG. 18A illustrates the type and block arrangement of the magnetoresistance element exhibiting the (b) bipolar symmetry and the (2) exponential increase property.

FIG. 18B illustrates the property of the magnetoresistance change with respect to the energization amount exhibited by each block of the magnetoresistance elements and the magnetic sensor (each resistor side) in FIG. 18A.

FIG. 19A illustrates the type and block arrangement of the magnetoresistance element exhibiting the (b) bipolar symmetry and (3) monotonic increase property.

FIG. 19B illustrates the property of the magnetoresistance change with respect to the energization amount exhibited by each block of the magnetoresistance elements and the magnetic sensor (each resistor side) in FIG. 19A.

FIG. 20A illustrates the type and block arrangement of the magnetoresistance element exhibiting the (b) bipolar symmetry and (4) arbitrary increase property.

FIG. 20B illustrates the property of the magnetoresistance change with respect to the energization amount exhibited by each block of the magnetoresistance elements and the magnetic sensor (each resistor side) in FIG. 20A.

FIG. 21A illustrates the type and block arrangement of the magnetoresistance elements exhibiting the (a) unipolar and (1) logarithmic increase property.

FIG. 21B illustrates the property of the magnetoresistance change with respect to the energization amount exhibited by each block of the magnetoresistance elements and the magnetic sensor (each resistor side) in FIG. 21A.

FIG. 22A illustrates the type and block arrangement of the magnetoresistance element exhibiting the (a) unipolar and (2) exponential increase property.

FIG. 22B illustrates the property of the magnetoresistance change with respect to the energization amount exhibited by each block of the magnetoresistance elements and the magnetic sensor (each resistor side) in FIG. 22A.

FIG. 23A illustrates the type and block arrangement of the magnetoresistance element exhibiting the (a) unipolar and (3) monotonic increase property.

FIG. 23B illustrates the property of the magnetoresistance change with respect to the energization amount exhibited by each block of the magnetoresistance elements and the magnetic sensor (each resistor side) in FIG. 23A.

FIG. 24A illustrates the type and block arrangement of the magnetoresistance element exhibiting the (a) unipolar and (4) arbitrary increase property.

FIG. 24B illustrates the property of the magnetoresistance change with respect to the energization amount exhibited by each block of the magnetoresistance elements and the magnetic sensor (each resistor side) in FIG. 24A.

FIG. 25A illustrates the type and block arrangement of the magnetoresistance element exhibiting the (c) bipolar asymmetry and (3) monotonic increase property.

FIG. 25B illustrates the property of the magnetoresistance change with respect to the energization amount exhibited by each block of the magnetoresistance elements and the magnetic sensor (each resistor side) in FIG. 25A.

FIG. 26A illustrates the type and block arrangement of the magnetoresistance element exhibiting the (c) bipolar asymmetry and (3) monotonic increase property.

FIG. 26B illustrates the property of the magnetoresistance change with respect to the energization amount exhibited by each block of the magnetoresistance elements and the magnetic sensor (each resistor side) in FIG. 26A.

FIG. 27A illustrates a state of a lead frame forming process in a manufacturing flow of the current sensor.

FIG. 27B illustrates a state of an installation process of the magnetic sensor in the manufacturing flow of the current sensor.

FIG. 27C illustrates a state of a wire bonding process in the manufacturing flow of the current sensor.

FIG. 27D illustrates a state of a molding process in the manufacturing flow of the current sensor.

FIG. 28 illustrates the internal configuration of the current sensor according to a modification example in the top view.

### DESCRIPTION OF EXEMPLARY EMBODIMENTS

Hereinafter, embodiments of the present invention will be described. However, the following embodiments are not for limiting the invention according to the claims. In addition, not all of the combinations of features described in the embodiments are essential to the solution of the invention.

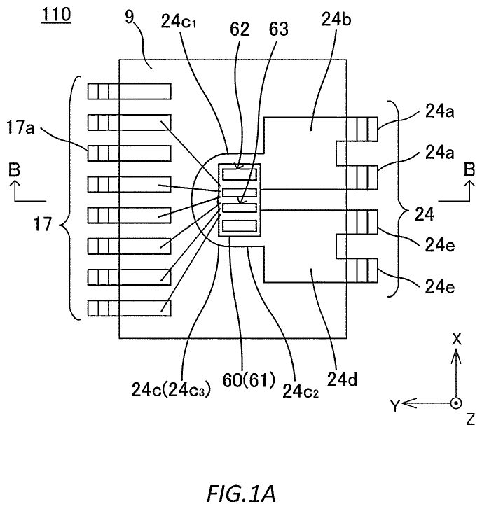

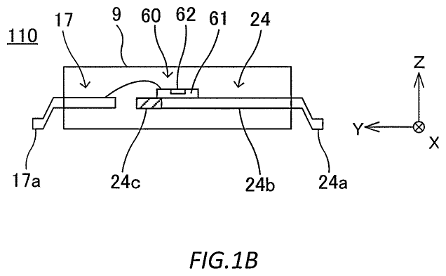

FIG. 1A and FIG. 1B illustrate an internal configuration of a current sensor 110 according to the present embodiment in a top view and a side view, respectively, without a package 9. Herein, FIG. 1B illustrates a cross-sectional structure of the current sensor 110 with respect to a reference line BB in FIG. 1A. Note that the up-down direction in FIG. 1A is referred to as the X axis direction and the left-right direction in FIG. 1A and FIG. 1B is referred to as the Y axis direction, and the up-down direction in FIG. 1B is referred to as the Z axis direction. The current sensor 110 is a sensor that measures a current amount by using a magnetic sensor 60 to detect a magnetic field generated around the conductor 24 as a result of a to-be-measured current flows through the conductor 24 and especially a current sensor exhibiting a dual linearity or multi-linearity according to the to-be-measured current and a magnetic sensor used for the current sensor are provided. The current sensor 110 includes the package 9, the plurality of device terminals 17, the conductor 24, and the magnetic sensor 60.

The package 9 is a member that seals and protects each component of the current sensor 110 (in particular, the conductor 24 and the magnetic sensor 60) therein except for the terminal portion of each of the plurality of device terminals 17 and the conductor 24. The package 9 is formed of a sealing resin with a good insulating property such as epoxy, for example, that is shaped into a flat cuboid by molding.

The plurality of device terminals 17 (an example of the plurality of output terminals) are secondary conductors that are each connected to the electrode pad (not shown) of the magnetic sensor 60 and outputs, to the external device, the detection result of the magnetic field intensity output from the magnetic sensor 60. In the present example, as an example, eight device terminals 17 are arrayed at equal intervals on the left side of the package 9 with their longitudinal side oriented in the Y axis direction. The device terminal 17 is made of metal formed into a rectangular-shaped plate and, at the end portion, has each terminal portion 17a formed by bending the end portion downward by a bending process and further bending the tip horizontally.

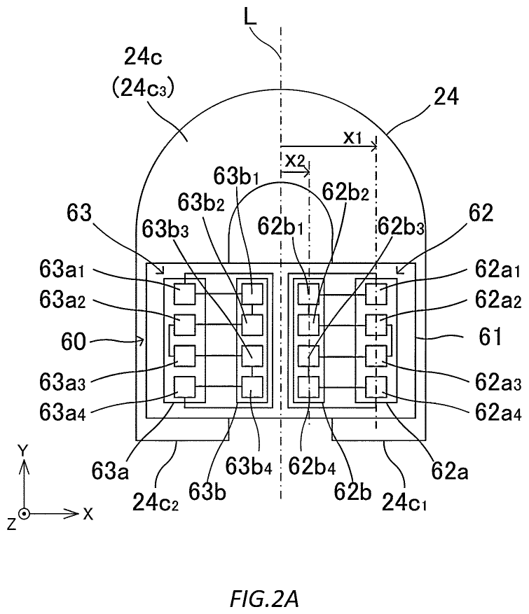

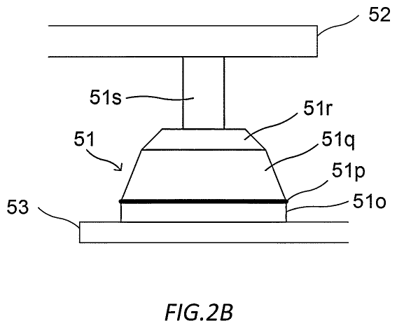

The conductor 24 is a primary conductor that forms a current path in which the to-be-measured current flows. In the present embodiment, the conductor 24 has a U-shape or an approximately U-shape (or may be a right-angle U-shape, a n shape, or a V-shape) including two arms 24c₁, 24c₂ that are symmetrical or approximately symmetrical with respect to a reference line L (see FIG. 2A) and is arranged such that it extends from a current terminal 24a, which is provided on one side of the right side of the package 9 (that is, the upper side in FIG. 1A), through the inside of the package 9 and returns to the right side to reach the current terminal 24e, which is provided on the other side of the right side (that is, the lower side in FIG. 1A). The conductor 24 is formed of conductive metal. The conductor 24 includes current terminals (also simply referred to as a terminal portion) 24a, 24e, barrel portions 24b, 24d, and a curved portion 24c.

Each of the terminal portions 24a, 24e forms a terminal for inputting a current, by protruding from the right side of the package 9, bending their end portion downward by a bending process, and further bending the tip to be positioned horizontally.

The barrel portions 24b, 24d are portions connecting the terminal portions 24a, 24e to the curved portion 24c. The barrel portions 24b, 24d are formed into a rectangular shape as an example, are connected on the right side to two terminal portions 24a, 24e, which are spaced apart, and are connected on the left side to the arms 24c₁, 24c₂ of the curved portion 24c, respectively.

The curved portion 24c has two arms 24c₁, 24c₂ and a joining portion 24c₃ that joins these two arms 24c₁, 24c₂. The two arms 24c₁, 24c₂ have shapes that have a width in the X axis direction and extend in the Y axis direction. In other words, the two arms 24c₁, 24c₂ may extend on the same side with respect to a joining portion 24c₃. Each width is smaller than the width of the barrel portions 24b, 24d. The joining portion 24c₃ curves in an approximately arc shape, and the both ends are connected to the two arms 24c₁, 24c₂, which are spaced apart from each other in the X axis direction. The joining portion 24c₃ may be bent in a right-angle U-shape. In the curved portion 24c, the to-be-measured current is input into one arm among the two arms 24c₁, 24c₂, and the to-be-measured current is output from the other arm via the joining portion 24c₃.

The conductor 24 is sealed within the package 9, in which the two arms 24c₁, 24c₂ included in the curved portion 24c are disposed at the center of the package 9 and the terminal portions 24a, 24e are protruded from the right side of the package 9.

FIG. 2A illustrates an example of the arrangement and substrate layout of the full bridge magnetic sensor 60. The magnetic sensor 60 is a sensor for detecting a magnetic field generated around the conductor 24 as a result of the to-be-measured current energizing the conductor 24. As an example, the magnetic sensor 60 is configured to detect the magnetic field in the X axis direction generated on the top surface of the conductor 24 (an example of the magnetic field in the horizontal direction) and includes a substrate 61, a plurality of magnetoresistance elements 51, and a plurality of electrode pads (not shown).

The substrate 61 is a plate-shaped member holding two magneto-electric conversion units 62, 63 and is installed such that it bridges between the two arms 24c₁, 24c₂ on the conductor 24 in the present example. The substrate 61 is formed of silicon (Si), for example, and a plurality of blocks arrayed in the direction (that is, the X axis direction) intersecting the energization direction of the conductor 24 are arranged on its one surface. In the present example, the plurality of blocks include first blocks 62a, 63a positioned at or near the center line of each of the arms 24c₁, 24c₂ of the conductor 24 (that is, the location with a relatively high magnetic field intensity) and second blocks 62b, 63b positioned far from the arms 24c₁, 24c₂ (that is, the location with a relatively low magnetic field intensity, and between the arms 24c₁, 24c₂ in the present example), relative to each other. The first blocks 62a, 63a and the second blocks 62b, 63b are each arranged on one of the two arms 24c₁, 24c₂ or on one of the sides of each arm, respectively, in a symmetrical manner with respect to the reference line L. Note that the plurality of blocks is not limited to two but may include three or more blocks.

The first blocks 62a, 63a and the second blocks 62b, 63b include one or more (four in the present example) subblocks 62a₁ to 62a₄, 62b₁ to 62b₄, 63a₁ to 63a₄, 63b₁ to 63b₄, respectively. Furthermore, on one surface of the substrate 61, a plurality of wires are laid, which electrically connect the plurality of blocks 62a, 62b, 63a, 63b or the plurality of subblocks 62a₁ to 62a₄, 62b₁ to 62b₄, 63a₁ to 63a₄, 63b₁ to 63b₄ therein.

The plurality of magnetoresistance elements 51 are the elements that vary in the resistance value according to the application of magnetic field, and are disposed on one side and the other side of the substrate 61, respectively, in the X axis direction to form the two magneto-electric conversion units 62, 63. The magneto-electric conversion unit 62 is formed by assembling a part of the plurality of magnetoresistance elements 51 (that is, the magnetoresistance element 51 disposed on the right side in FIG. 2A) into the Wheatstone bridge or the half-bridge. Herein, a subpart of the part of the magnetoresistance elements 51 is disposed in the first block 62a and another subpart is disposed in the second block 62b. The magneto-electric conversion unit 63 is formed by assembling another part of the plurality of magnetoresistance elements 51 (that is, the magnetoresistance element 51 disposed on the left side in FIG. 2A) into the Wheatstone bridge (or the half-bridge). Herein, a subpart of the another part of the magnetoresistance element 51 is disposed in the first block 63a and another subpart is disposed in the second block 63b. Note that, for example, the tunnel magnetoresistance element (TMR) or the giant magnetoresistance element (GMR) may be employed as a magnetoresistance element.

FIG. 2B illustrates the configuration of the magnetoresistance element 51 in a side view. The magnetoresistance element 51 is an element that varies in the resistance value according to the application of magnetic field, and has a fixed layer 51o, a tunnel layer 51p, a free layer 51q, and a cap layer 51r. The fixed layer 51o is a magnetic film whose orientation of magnetization is fixed. The fixed layer 51o is magnetized such that its magnetization is oriented in a uniaxial direction in a plane on which the magnetic film spreads (also referred to as a magnetic sensing surface) or in a direction perpendicular to the magnetic sensing surface. The orientation of magnetization of the fixed layer 51o defines a magnetic field detection direction of the magnetoresistance element 51. The tunnel layer 51p is, for example, a non-magnetic insulating film with a thickness of several nanometers. The free layer 51q is a magnetic film that changes the orientation of magnetization according to the external magnetic field. It should be noted that, as the material of the magnetic film, an alloy including, for example, at least one of Co, Fe, B, Ni, or Si and more specifically cobalt iron (CoFe), cobalt iron boron (CoFeB), or nickel iron (NiFe) can be used. The fixed layer 51o, the tunnel layer 51p, and the free layer 51q are stacked to constitute a stack. Herein, an electron tunnels through the tunnel layer 51p and moves from the fixed layer 51o to the free layer 51q or from the free layer 51q to the fixed layer 51o, causing the current to flow through the element in the stack direction. The cap layer 51r is a member covering the stack from above and can be made of an alloy including at least one of, for example, Ta, Ru, Pt, Mn, Ir, Mg, Cu, Fe, Ni, Cr, Fe, Co, or Al, more specifically, platinum manganese (PtMn) or iridium manganese (IrMn). It should be noted that a region around the magnetoresistance element 51 is covered with an insulator (not shown), for example, silicon dioxide (SiO₂), silicon nitride (SiN), or the like.

When the external magnetic field is applied to the magnetoresistance element 51, the orientation of the magnetization of the free layer 51q changes according to the orientation and intensity of the magnetic field due to the magnetoresistance effect (MR effect), in other words, the orientation of the magnetization of the free layer 51q changes with respect to the orientation of the magnetization of the fixed layer 51o, causing the variation in the resistance value (the magnetoresistance) between the fixed layer 51 and the free layer 51q. In particular, if the orientation of the magnetization of the free layer 51q is the same as the orientation of the magnetization of the fixed layer 51o (that is, the magnetizations of the two layers are parallel to each other), the resistance value is low, or if it is opposite (that is, the magnetizations of the two layers are anti-parallel), the resistance value is high.

It should be noted that connecting a plurality of magnetoresistance elements 51 in series can improve a DC voltage resistance. Herein, by connecting the electrode piece 52 to the cap layer 51r via the electrode rod 51s and connecting the electrode piece 53 to the lower surface of the fixed layer 51o, the magnetoresistance element 51 can be connected to another magnetoresistance element 51 via these electrode pieces 52, 53. In other words, the plurality of magnetoresistance elements 51 can be arrayed in a plane. In addition, the plurality of magnetoresistance element 51 can be arrayed three-dimensionally by connecting the cap layer 51r of the magnetoresistance element 51 to the fixed layer 51o of another magnetoresistance element 51 via the electrode rod 51s. In the present example, in particular, for each of the plurality of subblocks 62a₁ to 62a₄, 62b₁ to 62b₄, 63a₁ to 63a₄, 63b₁ to 63b₄, the plurality of magnetoresistance elements 51, which are disposed for each, are connected in series by the electrode pieces 52, 53 to form a part of the resistor side.

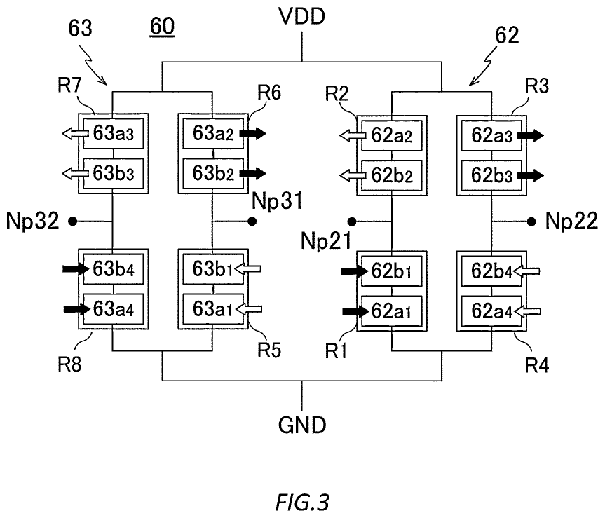

FIG. 3 illustrates the circuit configuration of the full bridge magnetic sensor 60 (the two magneto-electric conversion units 62, 63) and the magnetic field detection direction (also referred to as the magnetic sensing direction) of the resistor sides R1 to R8 (the magnetoresistance element 51 included in each of them). The two magneto-electric conversion units 62, 63 are connected in parallel between the drive terminal VDD and the ground terminal GND in the magnetic sensor 60. As described above, the first blocks 62a, 63a and the second blocks 62b, 63b arranged on the substrate 61 include four subblocks 62a₁ to 62a₄, 62b₁ to 62b₄, 63a₁ to 63a₄, 63b₁ to 63b₄, respectively.

In the magneto-electric conversion unit 62 (also in the magneto-electric conversion unit 63), the magnetoresistance elements 51 having the magnetic sensing directions that are directions identical to each other as indicated with the black arrows (white arrows) are disposed in the first subblocks 62a₁, 62b₁ (63a₁, 63b₁) included in the first block 62a (63a) and the second block 62b (63b), respectively. The magnetoresistance element 51 in the first subblock 62a₁ (63a₁) of the first block 62a (63a) and the magnetoresistance element 51 in the first subblock 62b₁ (63b₁) of the second block 62b (63b) are connected in series to form the resistor side R1 (R5).

In the second subblocks 62a₂, 62b₂ (63a₂, 63b₂) included in the first block 62a (63a) and the second block 62b (63b), respectively, the magnetoresistance elements 51 having the magnetic sensing directions that are directions identical to each other as indicated with the white arrows (black arrows) and are directions opposite to those of the magnetoresistance elements 51 in the first subblocks 62a₁, 62b₁ (63a₁, 63b₁) are disposed. The magnetoresistance element 51 in the second subblock 62a₂ (63a₂) of the first block 62a (63a) and the magnetoresistance element 51 in the second subblock 62b₂ (63b₂) of the second block 62b (63b) are connected in series to form the resistor side R2 (R6).

In the third subblocks 62a₃, 62b₃ (63a₃, 63b₃) included in the first block 62a (63a) and the second block 62b (63b), respectively, the magnetoresistance elements 51 having the magnetic sensing directions that are directions identical to each other as indicated with the black arrows (white arrows) and are directions identical to those of the magnetoresistance elements 51 in the first subblocks 62a₁, 62b₁ (63a₁, 63b₁) are disposed. The magnetoresistance element 51 in the third subblock 62a₃ (63a₃) of the first block 62a (63a) and the magnetoresistance element 51 in the third subblock 62b₃ (63b₃) of the second block 62b (63b) are connected in series to form the resistor side R3 (R7).

In the fourth subblocks 62a₄, 62b₄ (63a₄, 63b₄) included in the first block 62a (63a) and the second block 62b (63b), respectively, the magnetoresistance elements 51 having magnetic sensing directions that are directions identical to each other as indicated with the white arrows (black arrows) and are directions opposite to those of the magnetoresistance elements 51 in the first subblocks 62a₁, 62b₁ (63a₁, 63b₁), that is, directions identical to those of the magnetoresistance elements 51 in the second subblocks 62a₂, 62b₂ (63a₂, 63b₂) are disposed. The magnetoresistance element 51 in the fourth subblock 62a₄ (63a₄) of the first block 62a (63a) and the magnetoresistance element 51 in the fourth subblock 62b₄ (63b₄) of the second block 62b (63b) are connected in series to form the resistor side R4 (R8).

The resistor sides R1, R2 (R5, R6) are connected in series to each other to form the output terminal Np21 (Np31) therebetween, the resistor sides R3, R4 (R7, R8) are connected in series to each other to form the output terminal Np22 (Np32) therebetween and are connected in parallel to the resistor sides R1, R2 (R5, R6), and the resistor sides R1 to R4 (R5 to R8) are assembled into the Wheatstone bridge circuit.

Note that, in the current sensor 110 according to the present embodiment, the magnetic sensing direction of the resistor sides R1 to R4 (R5 to R8) is the uniaxial direction parallel to the top surface of the conductor 24 (the X axis direction in FIG. 1A). The magnetic sensing directions of the magnetoresistance elements 51 forming each of the resistor sides R1, R3 (R6, R8) are identical to each other (indicated with the black arrows in FIG. 3) and are referred to as the +X direction (or the −X direction) in FIG. 1A in the present example. The magnetic sensing directions of the magnetoresistance elements 51 forming each of the resistor sides R2, R4 (R5, R7) are also identical to each other (indicated with the white arrows in FIG. 3) and are referred to as the −X direction (or the +X direction) in FIG. 1A in the present example. The magnetic field detection direction of the resistor sides R1, R3 (R6, R8) are opposite to the magnetic sensing direction of the resistor sides R2, R4 (R5, R7).

At least a part of the magneto-electric conversion unit 62 (63) is arranged on the arm 24c₁ (24c₂) of the conductor 24. When the to-be-measured current flows through the conductor 24 and the magnetic field is generated around the conductor 24, the magnetic field in the X axis direction is applied to the magnetoresistance elements 51 included in the resistor sides R1 to R4 (R5 to R8) of the magneto-electric conversion unit 62 (63) arranged on the arm 24c₁ (24c₂) of the conductor 24 and each resistance value (also referred to as the magnetoresistance) varies. For example, the resistance values of the resistor sides R1, R3 (R5, R7) increase (or decrease) and the resistance values of the resistor sides R2, R4 (R6, R8) decrease (or increase), disrupting the resistance balance of the resistor sides R1 to R4 (R5 to R8). Herein, the magnetic field intensity can be detected by inputting the drive voltage into drive terminal VDD relative to the ground terminal GND and detecting the differential voltage output between the output terminals Np21, Np22 (Np31, Np32). In this way, the horizontal magnetic field generated on the top surface of the arm 24c₁ (24c₂) can be detected.

When the to-be-measured current flows through the conductor 24 and the magnetic field Bx parallel to the X axis direction is generated above the conductor 24 (the arms 24c₁, 24c₂), the magnetoresistance of the magnetoresistance element 51 included in each of the magneto-electric conversion units 62, 63 linearly varies according to the intensity of the applied magnetic field Bx and reaches the magnetic saturation (that is, the magnetoresistance becomes constant) when the intensity of the magnetic field Bx reaches the detection limit. Herein, if the plurality of magnetoresistance element 51 are each formed in a similar manner, they exhibit a similar magnetic sensing property. However, the intensity of the magnetic field Bx increases or decreases according to the position relative to the conductor 24 (the arms 24c₁, 24c₂), for example, it is highest at the center line of each of the arms 24c₁, 24c₂ or around the center line and is attenuated in the region between or outside the arms 24c₁, 24c₂. Thus, arranging the plurality of magnetoresistance elements 51 constituting the magneto-electric conversion units 62, 63 at different locations relative to the conductor 24 (the arms 24c₁, 24c₂) can achieve the multi-linear sensor having a plurality of linearities with different sensitivities.

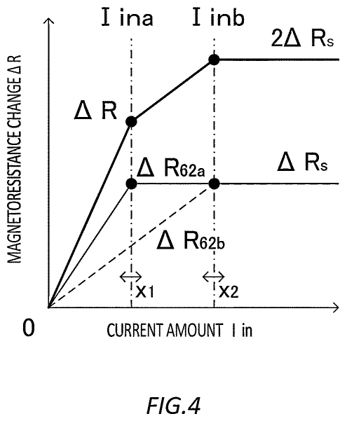

FIG. 4 illustrates the magnetoresistance change ΔR of the magnetoresistance elements 51 in the first block 62a and the second block 62b and the entire sensor (the magneto-electric conversion unit 62) with respect to the current amount Iin of the conductor 24. Note that, since the output voltage Vout of the magnetic sensor 60 (the magneto-electric conversion units 62, 63) is proportional to the magnetoresistance change ΔR, the linearity of the output voltage Vout with respect to the current amount Iin is equal to the linearity of the magnetoresistance change ΔR. Thus, unless otherwise stated, the linearity of the magnetoresistance change ΔR is described.

Since the first block 62a is positioned on or near the center line of the arm 24c₁ on the substrate 61 (the position x₁), approximately the highest intensity of magnetic field Bx is applied to the magnetoresistance element 51 disposed therein so that the magnetoresistance ΔR₆₂ₐ increases with a high sensitivity with respect to the current amount Iin and reaches the magnetic saturation (ΔRₛ) at a low current amount Iina or more. Note that, the sensitivity varies according to the position x₁ of the first block 62a. On the other hand, since the second block 62b is positioned far from the arm 24c₁ (at the position x₂ between the two arms 24c₁, 24c₂ in the present example), a relatively low magnetic field Bx is applied to the magnetoresistance element 51 disposed therein so that the magnetoresistance ΔR_{62b} increases with a low sensitivity with respect to the current amount Iin and reaches the magnetic saturation (ΔRₛ) at a relatively high current amount Iinb or more. Note that the sensitivity varies according to the position x₂ of the second block 62b.

The magnetoresistance elements 51 in the first block 62a (the subblocks 62a₁ to 62a₄) and the magnetoresistance elements 51 in the second block 62b (the subblocks 62b₁ to 62b₄) are connected in series to form the resistor sides R1 to R4 so that, with respect to the to-be-measured current Iin, the magnetoresistance change ΔR for each of the resistor sides R1 to R4 exhibits dual linearity, in which it increases with a high sensitivity (that is, a large slope) in the range equal to or less than the current amount Iina and increases with a low sensitivity (a small slope) in the range of the current amounts Iina to Iinb, and reaches the magnetic saturation at the current amount Iinb or more. Herein, the magnetoresistance elements 51 in the first block 62a and the magnetoresistance elements 51 in the second block 62b may have the same structure and can be formed by the same process. In addition, since they require no amplifier to achieve the plurality of linearities, they can constitute the magnetic sensor 60 with a small chip area.

Note that, since the structures and processes of the plurality of magnetoresistance elements 51 are the same, the magnetoresistance change ΔR of the magnetoresistance elements 51 in the first block 63a and the second block 63b and the magneto-electric conversion unit 63 with respect to the energization amount of the conductor 24 is similar to the magnetoresistance change ΔR of the magnetoresistance elements 51 in the first block 62a and the second block 62b and the magneto-electric conversion unit 62.

Note that, the two magneto-electric conversion units 62, 63 can be arranged on one side and the other side of the X axis direction in a symmetrical manner with respect to the reference line L (see FIG. 2A), respectively. In this way, the disturbance magnetic field can be canceled. In addition, the drive terminals VDD, the ground terminals GND, and the output terminals Np21, Np22, Np31, Np32 of the two magneto-electric conversion units 62, 63 may be connected to a plurality of electrode pads on the substrate 61.

The plurality of electrode pads are the pads that are disposed on the substrate 61, are wired to the drive terminals VDD and the ground terminals GND of the two magneto-electric conversion units 62, 63, the two output terminals Np21, Np22 of the magneto-electric conversion unit 62, and the two output terminals Np31, Np32 of the magneto-electric conversion unit 63, input the drive voltage from the outside to the drive terminals VDD, and output the differential voltage from the output terminals Np21, Np22, Np31, Np32 to the outside. The electrode pads, which are made of conductive metal such as gold, copper, or aluminium, are formed on the substrate 61 and are aligned in the X axis direction on the +Y side (the left side in FIG. 1A), for example.

The magnetic sensor 60 is arranged on the curved portion 24c of the conductor 24. In this way, the two magneto-electric conversion units 62, 63 are arranged on the two arms 24c₁, 24c₂ of the curved portion 24c, respectively, and the plurality of electrode pads on the substrate 61 connected to those drive terminals VDD, ground terminals GND, and output terminals Np21, Np22, Np31, Np32 are connected to the device terminal 17 via wire bonding. In this way, via the device terminal 17, the drive voltage can be applied to the two magneto-electric conversion units 62, 63 and also each differential voltage can be output.

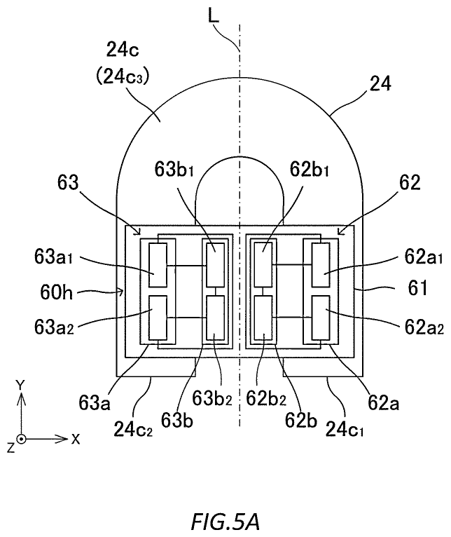

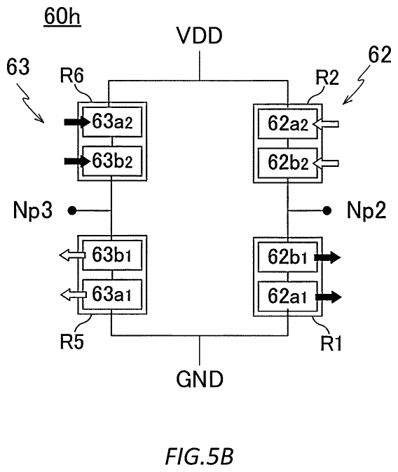

FIG. 5A illustrates an example of the arrangement and substrate layout of the half-bridge magnetic sensor 60h. The magnetic sensor 60h can be configured similarly to the magnetic sensor 60. However, the first blocks 62a, 63a and the second blocks 62b, 63b arranged on one surface of the substrate 61 include two of the subblocks 62a₁, 62a₂, 62b₁, 62b₂, 63a₁, 63a₂, 63b₁, 63b₂, respectively. Furthermore, on one surface of the substrate 61, a plurality of wires electrically connecting the plurality of blocks 62a, 62b, 63a, 63b or the plurality of subblocks 62a₁, 62a₂, 62b₁, 62b₂, 63a₁, 63a₂, 63b₁, 63b₂ therein are laid.

FIG. 5B illustrates the circuit configuration of the half-bridge magnetic sensor (the two magneto-electric conversion units 62, 63) and the magnetic sensing direction of the resistor sides R1, R2, R5, R6 (the magnetoresistance elements 51 included in each of them). The two magneto-electric conversion units 62, 63 are connected in parallel between the drive terminal VDD and the ground terminal GND in the magnetic sensor 60. As described above, the first blocks 62a, 63a and the second blocks 62b, 63b arranged on the substrate 61 include the two subblocks 62a₁, 62a₂, 62b₁, 62b₂, 63a₁, 63a₂, 63b₁, 63b₂, respectively.

In the magneto-electric conversion unit 62 (also in the magneto-electric conversion unit 63), the magnetoresistance elements 51 having the magnetic sensing directions that are directions identical to each other as indicated with the black arrows (white arrows) are disposed in the first subblocks 62a₁, 62b₁ (63a₁, 63b₁) included in the first block 62a (63a) and the second block 62b (63b), respectively. The magnetoresistance elements 51 in the first subblock 62a₁ (63a₁) of the first block 62a (63a) and the magnetoresistance elements 51 in the first subblock 62b₁ (63b₁) of the second block 62b (63b) are connected in series to form the resistor side R1 (R5).

In the second subblocks 62a₂, 62b₂ (63a₂, 63b₂) included in the first block 62a (63a) and the second block 62b (63b), respectively, the magnetoresistance elements 51 having the magnetic sensing directions that are directions identical to each other as indicated with the white arrows (black arrows) and are directions opposite to those of the magnetoresistance elements 51 in the first subblocks 62a₁, 62b₁ (63a₁, 63b₁) are disposed. The magnetoresistance element 51 in the second subblock 62a₂ (63a₂) of the first block 62a (63a) and the magnetoresistance element 51 in the second subblock 62b₂ (63b₂) of the second block 62b (63b) are connected in series to form the resistor side R2 (R6).

The resistor sides R1, R2 (R5, R6) are connected in series to each other to form an output terminal Np2 (Np3) therebetween and the resistor sides R1, R2 (R5, R6) are assembled into the half-bridge circuit.

Note that, in the magnetic sensor 60h according to the present example, the magnetic sensing direction of the resistor sides R1, R2 (R5, R6) is the uniaxial direction parallel to the top surface of the conductor 24 (the X axis direction in FIG. 1A). The magnetic sensing directions of the magnetoresistance elements 51 forming the resistor side R1 (R6) are identical to each other (indicated with black arrows in FIG. 5B) and are referred to as the +X direction (or the −X direction) in FIG. 1A in the present example. The magnetic sensing directions of the magnetoresistance elements 51 each forming the resistor side R2 (R5) are also identical to each other (indicated with white arrows in FIG. 5B) and are referred to as the −X direction (or the +X direction) in FIG. 1A in the present example. The magnetic field detection direction of the resistor side R1 (R6) is opposite to the magnetic sensing direction of the resistor side R2 (R5).

At least a part of the magneto-electric conversion unit 62 (63) is arranged on the arm 24c₁ (24c₂) of the conductor 24. When the to-be-measured current flows through the conductor 24 and the magnetic field is generated around the conductor 24, the magnetic field in the X axis direction is applied to the magnetoresistance element 51 included in the resistor sides R1, R2 (R5, R6) of the magneto-electric conversion unit 62 (63) arranged on the arm 24c₁ (24c₂) of the conductor 24 and each resistance value varies. For example, the resistance value of the resistor side R1 (R5) increases (or decreases) and the resistance value of the resistor side R2 (R6) decreases (or increases), disturbing the resistance balance of the resistor sides R1, R2 (R5, R6). Herein, the magnetic field intensity can be detected by inputting the drive voltage into the drive terminal VDD relative to the ground terminal GND and detecting the voltage output from the output terminal Np2 (Np3). In this way, the horizontal magnetic field generated on the top surface of the arm 24c₁ (24c₂) can be detected.

As with the magnetic sensor 60, in the magnetic sensor 60h, the plurality of magnetoresistance elements 51 constituting the magneto-electric conversion units 62, 63 are arranged at different locations relative to the conductor 24 (the arms 24c₁, 24c₂) so that the multi-linear sensor having a plurality of linearities with different sensitivities can be achieved.

The position x₁ of the first block 62a (63a) and the position x₂ of the second block 62b (63b) are selected so that the sensitivity (linearity) of the magnetoresistance element 51 in each block with respect to the to-be-measured current Iin can be adjusted. The arrangement near the center lines of the arms 24c₁, 24c₂, where the magnetic field Bx with the highest intensity is generated, can increase the sensitivity, while the arrangement near the outer side of the arms 24c₁, 24c₂ or on the region inward or outward with respect to 24c₁, 24c₂, where the magnetic field Bx is relatively weak, can reduce the sensitivity.

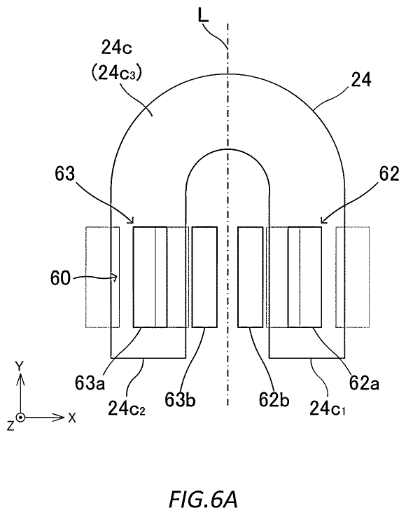

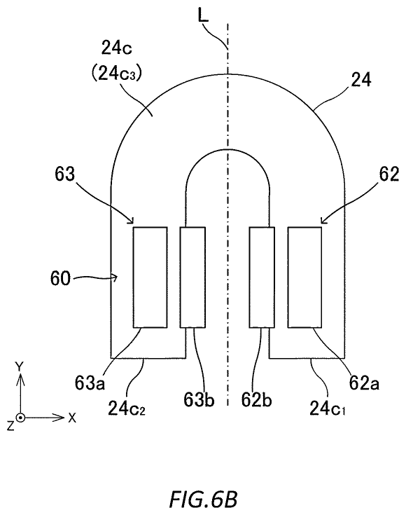

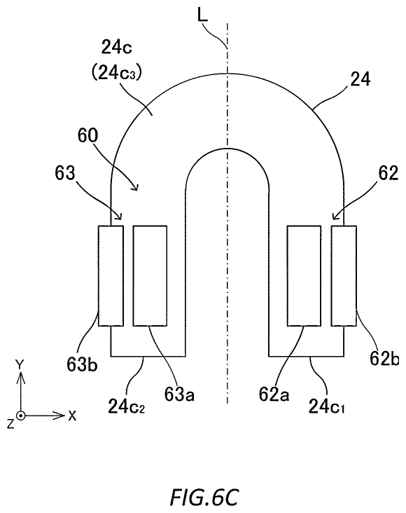

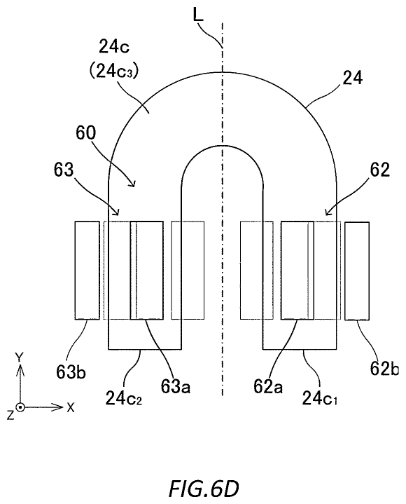

FIG. 6A to FIG. 6D illustrate an example of the arrangement of the first blocks 62a, 63a and the second blocks 62b, 63b. In both examples, the first blocks 62a, 63a of the magneto-electric conversion units 62, 63 are arranged in a symmetrical manner with respect to the reference line L and the second blocks 62b, 63b of the magneto-electric conversion units 62, 63 are also arranged in a symmetrical manner with respect to the reference line L.

In the example illustrated in FIG. 6A, in the plan view (that is, viewed in the Z axis direction), at least a part of the first blocks 62a, 63a are positioned on the arms 24c₁, 24c₂ of the conductor 24, respectively, and the second blocks 62b, 63b are positioned outside the arms 24c₁, 24c₂. In the present example, in particular, the first blocks 62a, 63a are positioned on the center lines of the arms 24c₁, 24c₂, respectively, and the second blocks 62b, 63b are positioned between the arms 24c₁, 24c₂. Note that, as illustrated with the dotted line in the figure, the first blocks 62a, 63a may be positioned on the inner side or outer side of the arms 24c₁, 24c₂, respectively. Such an arrangement enables the magnetoresistance element 51 to be disposed in a small chip area.

In the example illustrated in FIG. 6B, in the plan view, the first blocks 62a, 63a are positioned on the arms 24c₁, 24c₂ of the conductor 24, respectively, and at least a part of the second blocks 62b, 63b are positioned on the arms 24c₁, 24c₂, respectively, and at least a part of them are positioned outside the arms 24c₁, 24c₂, respectively. In the present example, in particular, the first blocks 62a, 63a are positioned on or near the center line of the arms 24c₁, 24c₂, respectively, and a part of the second blocks 62b, 63b are positioned on the inner side of the arms 24c₁, 24c₂, respectively. Such an arrangement enables the magnetoresistance element 51 to be disposed in a small chip area.

In the example illustrated in FIG. 6C, in the plan view, the first blocks 62a, 63a are positioned on the arms 24c₁, 24c₂ of the conductor 24, respectively, and at least a part of the second blocks 62b, 63b are positioned on the arms 24c₁, 24c₂, respectively, and at least a part of them are positioned outside the arms 24c₁, 24c₂, respectively. In the present example, in particular, the first blocks 62a, 63a are positioned on or near the center line of the arms 24c₁, 24c₂, respectively, and a part of the second blocks 62b, 63b are positioned on the outer side of the arms 24c₁, 24c₂, respectively.

In the example illustrated in FIG. 6D, in the plan view, at least a part of the first blocks 62a, 63a are positioned on the arms 24c₁, 24c₂ of the conductor 24, respectively, and the second blocks 62b, 63b are positioned outside the arms 24c₁, 24c₂. In the present example, in particular, the first blocks 62a, 63a are positioned on the center lines of the arms 24c₁, 24c₂, respectively, and the second blocks 62b, 63b are positioned outside the arms 24c₁, 24c₂. Note that, as illustrated with the dotted line in the figure, the first blocks 62a, 63a may be positioned on the inner side or outer side of the arms 24c₁, 24c₂, respectively.

The plurality of blocks may further include at least one extension block that is arranged at the position on one surface of the substrate 61 and spaced apart from the first blocks 62a, 63a and the second blocks 62b, 63b. In such a case, yet another part of the plurality of magnetoresistance elements 51 is disposed in the at least one extension block.

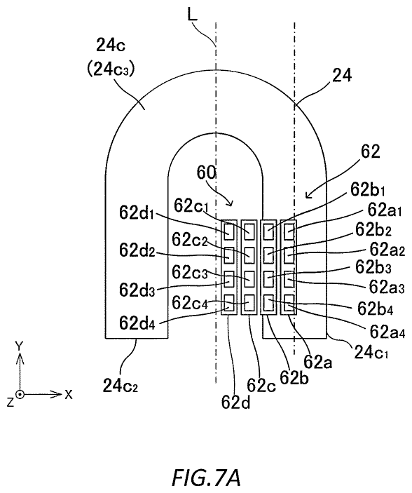

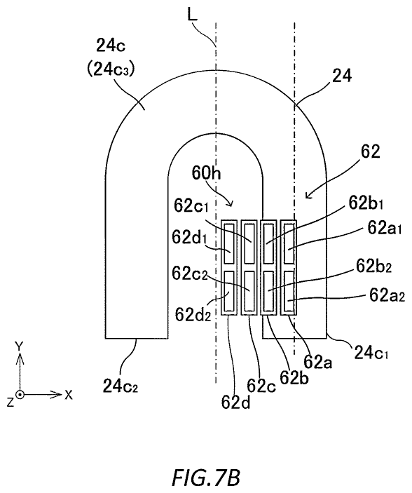

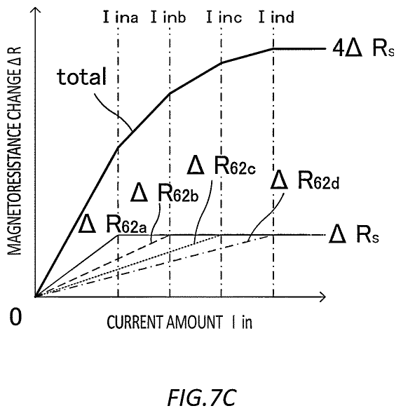

FIG. 7A illustrates the block arrangement of the magnetoresistance elements 51 constituting the quadruple linear current sensor 110 having the sensitivity that decreases as the energization amount increases, using the full bridge magnetic sensor 60. In the magnetic sensor 60 of the present example, the plurality of blocks arranged on the substrate 61 (not shown in FIG. 7A) further include two extension blocks, that is, the third block 62c and the fourth block 62d, in addition to the first block 62a and the second block 62b illustrated in FIG. 2A. However, four blocks where the magnetoresistance elements 51 forming each of the magneto-electric conversion units 62, 63 are disposed are arranged in a symmetrical manner with respect to the reference line L. Thus, only four blocks 62a to 62d in the magneto-electric conversion unit 62 are illustrated and four blocks in the magneto-electric conversion unit 63 are not shown.

As with the first block 62a and the second block 62b, the third block 62c and the fourth block 62d include one or more (four in the present example) subblocks 62c₁ to 62c₄, 62d₁ to 62d₄, respectively. Furthermore, on one surface of the substrate 61, a plurality of wires (not shown) are laid, which electrically connect the plurality of blocks 62a, 62b, 62c, 62d or the plurality of subblocks 62a₁ to 62a₄, 62b₁ to 62b₄, 62c₁-62c₄, 62d₁-62d₄ therein. As with the magneto-electric conversion unit 62, each of the plurality of blocks in the magneto-electric conversion unit 63 also includes four subblocks and is provided with a plurality of wires electrically connecting them.

For each of the plurality of subblocks 62a₁ to 62a₄, 62b₁ to 62b₄, 62c₁ to 62c₄, 62d₁ to 62d₄, the plurality of magnetoresistance elements 51 are connected in series by the electrode pieces 52, 53 to form a part of the resistor sides R1 to R4.

In the magneto-electric conversion unit 62, the magnetoresistance elements 51 having the magnetic sensing directions that are directions identical to each other are disposed in the first subblocks 62a₁, 62b₁ included in the first block 62a and the second block 62b, respectively. In the first subblocks 62c₁, 62d₁ included in the third block 62c and the fourth block 62d, respectively, the magnetoresistance elements 51 having magnetic sensing directions that are directions identical to each other and are directions identical to those of the magnetoresistance elements 51 in the first subblock 62a₁ of the first block 62a and those of the magnetoresistance elements 51 in the first subblock 62b₁ of the second block 62b are also disposed. The magnetoresistance element 51 in the first subblock 62c₁ of the third block 62c and the magnetoresistance element 51 in the first subblock 62d₁ of the fourth block 62d are connected in series to the magnetoresistance element 51 in the first subblock 62a₁ of the first block 62a and the magnetoresistance element 51 in the first subblock 62b₁ of the second block 62b to form the resistor side R1.

In the second subblocks 62a₂ to 62d₂ included in the first to fourth blocks 62a to 62d, respectively, the magnetoresistance elements 51 having the magnetic sensing directions that are directions identical to each other and are directions opposite to those of the magnetoresistance elements 51 in each of the first subblock 62a₁ to 62d₁ are further disposed. The magnetoresistance elements 51 in the second subblocks 62a₂ to 62d₂ included in the first to fourth blocks 62a to 62d, respectively, are connected in series to form the resistor side R2.

In the third subblocks 62a₃ to 62d₃ included in the first to fourth blocks 62a to 62d, respectively, the magnetoresistance elements 51 having the magnetic sensing directions that are directions identical to each other and are directions identical to those of the magnetoresistance element 51 in each of the first subblock 62a₁ to 62d₁ are further disposed. The magnetoresistance elements 51 in the third subblocks 62a₃ to 62d₃ included in the first to fourth blocks 62a to 62d, respectively, are connected in series to form the resistor side R3.

In the fourth subblocks 62a₄ to 62d₄ included in the first to fourth blocks 62a to 62d, respectively, the magnetoresistance elements 51 having the magnetic sensing directions that are directions identical to each other and are directions opposite to those of the magnetoresistance elements 51 in each of the first subblock 62a₁ to 62d₁ are further disposed. The magnetoresistance elements 51 in the fourth subblocks 62a₄ to 62d₄ included in the first to fourth blocks 62a to 62d, respectively, are connected in series to form the resistor side R4.

The resistor sides R1, R2 are connected in series to form the output terminal Np21 therebetween and the resistor sides R3, R4 are connected in series to each other to form the output terminal Np22 therebetween and are connected in parallel to the resistor sides R1, R2, and the resistor sides R1 to R4 are assembled into the Wheatstone bridge circuit (see FIG. 3). In other words, in the magnetic sensor 60 of the present example used for the quadruple linear current sensor 110, the each block 62a to 62d include four subblocks 62a₁ to 62a₄, 62b₁ to 62b₄, 62c₁ to 62c₄, 62d₁ to 62d₄, respectively, in which the magnetoresistance elements 51 are each disposed.

FIG. 7B illustrates a block arrangement of the magnetoresistance elements 51 constituting the quadruple linear current sensor 110 having the sensitivity that decreases as the energization amount increases, using the half-bridge magnetic sensor 60h. In the magnetic sensor 60h of the present example, the plurality of blocks arranged on the substrate 61 (not shown in FIG. 7B) further include two extension blocks, that is, the third block 62c and the fourth block 62d, in addition to the first block 62a and the second block 62b illustrated in FIG. 5A. However, four blocks where the magnetoresistance elements 51 forming each of the magneto-electric conversion units 62, 63 are disposed are arranged in a symmetrical manner with respect to the reference line L. Thus, only four blocks 62a to 62d in the magneto-electric conversion unit 62 are illustrated and four blocks in the magneto-electric conversion unit 63 are not shown.

As with the first block 62a and the second block 62b, the third block 62c and the fourth block 62d include two subblocks 62c₁, 62c₂, 62d₁, 62d₂, respectively. Furthermore, on one surface of the substrate 61, a plurality of wires (not shown) are laid, which electrically connect the plurality of blocks 62a, 62b, 62c, 62d or the plurality of subblocks 62a₁, 62a₂, 62b₁, 62b₂, 62c₁, 62c₂, 62d₁, 62d₂ therein. As with the magneto-electric conversion unit 62, each of the plurality of blocks in the magneto-electric conversion unit 63 also includes two subblocks and is provided with a plurality of wires to electrically connect them.

For each of the plurality of subblocks 62a₁, 62a₂, 62b₁, 62b₂, 62c₁, 62c₂, 62d₁, 62d₂, the plurality of magnetoresistance elements 51 are connected in series by the electrode pieces 52, 53 to form a part of the resistor sides R1 to R4 and these resistor sides R1 to R4 are assembled into the Wheatstone bridge circuit (see FIG. 3).

In the magneto-electric conversion unit 62, the magnetoresistance elements 51 having the magnetic sensing directions that are directions identical to each other are disposed in the first subblocks 62a₁, 62b₁ included in the first block 62a and the second block 62b, respectively. In the first subblocks 62c₁, 62d₁ included in the third block 62c and the fourth block 62d, respectively, the magnetoresistance elements 51 having magnetic sensing directions that are directions identical to each other and are directions identical to those of the magnetoresistance elements 51 in the first subblock 62a₁ of the first block 62a and those of the magnetoresistance elements 51 in the first subblock 62b₁ of the second block 62b are also disposed. The magnetoresistance element 51 in the first subblock 62c₁ of the third block 62c and the magnetoresistance element 51 in the first subblock 62d₁ of the fourth block 62d are connected in series to the magnetoresistance element 51 in the first subblock 62a₁ of the first block 62a and the magnetoresistance element 51 in the first subblock 62b₁ of the second block 62b to form the resistor side R1.

In the second subblocks 62a₂ to 62d₂ included in the first to fourth blocks 62a to 62d, respectively, the magnetoresistance elements 51 having the magnetic sensing directions that are directions identical to each other and are directions opposite to those of the magnetoresistance elements 51 in each of the first subblock 62a₁ to 62d₁ are further disposed. The magnetoresistance elements 51 in the second subblocks 62a₂ to 62d₂ included in the first to fourth blocks 62a to 62d, respectively, are connected in series to form the resistor side R2.

The resistor sides R1, R2 are connected in series to each other to form the output terminal Np2 therebetween and the resistor sides R1, R2 are assembled into the half-bridge circuit (see FIG. 5B). In other words, in the magnetic sensor 60h of the present example used for the quadruple linear current sensor 110, each block 62a to 62d include two subblocks 62a₁ to 62a₂, 62b₁ to 62b₂, 62c₁ to 62c₂, 62d₁ to 62d₂, respectively, in which the magnetoresistance elements 51 are each disposed.

FIG. 7C illustrates the magnetoresistance change ΔR of the magnetoresistance elements 51 of the four blocks 62a to 62d of the magnetic sensor 60 and each of the resistor sides R1 to R4 or R1, R2 in FIG. 7A and the magnetic sensor 60h in FIG. 7B with respect to the energization amount of the conductor 24. The four blocks 62a to 62d are sequentially arrayed in the X axis direction on the top surface of the substrate 61 from near the center line of the arm 24c₁ to the +X side of the reference axis L. In this way, the magnetoresistance element 51 included in the first block 62a (the subblocks 62a₁ to 62a₄ or 62a₁ to 62a₂), to which the magnetic field Bx with the highest intensity generated by the to-be-measured current energizing the conductor 24 is applied, has the highest sensitivity with respect to the current amount Iin and exhibits the magnetoresistance ΔR₆₂ₐ that reaches the magnetic saturation at a small current amount Iina or more. The magnetoresistance element 51 included in the second block 62b (the subblocks 62b₁ to 62b₄ or 62b₁ to 62b₂), to which the magnetic field Bx with a relatively high intensity generated by the to-be-measured current is applied, has the second highest sensitivity (less than the magnetoresistance ΔR₆₂ₐ) with respect to the current amount Iin and exhibits the magnetoresistance ΔR_{62b} that reaches the magnetic saturation at a small current amount Iinb (>Iina) or more. The magnetoresistance element 51 included in the third block 62c (the subblocks 62c₁ to 62c₄ or 62c₁ to 62c₂), to which the magnetic field Bx with a relatively low intensity generated by the to-be-measured current is applied, has a second highest sensitivity (less than the magnetoresistance ΔR_{62b}) with respect to the current amount Iin and exhibits the magnetoresistance ΔR_{62c} that reaches the magnetic saturation at a small current amount Iinc (>Iinb) or more. The magnetoresistance element 51 included in the fourth block 62d (the subblocks 62d₁ to 62d₄ or 62d₁ to 62d₂), to which the magnetic field Bx with the lowest intensity generated by the to-be-measured current is applied, has the lowest sensitivity (less than the magnetoresistance ΔR_{62c}) with respect to the current amount Iin and exhibits the magnetoresistance ΔR_{62d} that reaches the magnetic saturation at the largest current amount Iind (>Iinc) or more.

The magnetoresistance change ΔR (total) for each of the resistor sides R1 to R4 or R1, R2 is given by a linear sum of the magnetoresistances ΔR₆₂ₐ, ΔR_{62b}, ΔR_{62c}, ΔR_{62d} of the magnetoresistance elements 51 in the four blocks 62a to 62d. Therefore, the magnetoresistance change ΔR exhibits quadruple linearity, in which, with respect to the to-be-measured current Iin, it increases with the highest sensitivity (that is, the largest slope) in the range of the current amounts 0 to Iina, increases with the next highest sensitivity (the next largest slope) in the range of the current amounts Iina to Iinb, increases with a low sensitivity (a small slope) in the range of the current amounts Iinb to Iinc, increases with the lowest sensitivity (the smallest slope) in the range of the current amounts Iinc to Iind, and reaches the magnetic saturation at the current amount Iind or more.

Herein, the four sensitivities in the quadruple linearity can be adjusted by the positions of the four blocks 62a to 62d on the substrate 61 in the X axis direction. In addition, the magnetoresistance elements 51 in the first to fourth blocks 62a to 62d may have the same structure and can be formed by the same process, and can constitute the magnetic sensors 60, 60h with a small chip area since they require no amplifier for achieving a plurality of linearities.

At least one magnetoresistance element 51 among the plurality of magnetoresistance elements 51 may have a free layer 51q to which the bias magnetic field is applied. Herein, the bias magnetic field can be applied by any of the magnetic coupling of the antiferromagnetic material to the free layer 51q, the magnetic coupling by the synthetic ferrimagnetic structure (SyF, that is, the structure in which the magnetizations of the two ferromagnetic materials are coupled in anti-parallel via a non-magnetic middle layer) to the free layer 51q which is a ferromagnetic material, the arrangement of the magnet near the free layer 51q, and the arrangement of the energized coil wiring near the free layer 51q. In this way, when an external magnetic field in the direction opposite to that of the bias magnetic field applied to the free layer 51q is applied to the magnetoresistance element 51, the magnetoresistance ΔR of the magnetoresistance element 51 does not vary at the intensity of the external magnetic field lower than the bias magnetic field, which causes the exchange bias to act to fix the orientation of the magnetization of the free layer 51q, varies linearly at the intensity of the external magnetic field higher than the bias magnetic field, which causes the external magnetic field to offset the action of the exchange bias to change the orientation of the magnetization of the free layer 51q, and reaches the magnetic saturation at a further higher intensity of the external magnetic field. Herein, when the intensity of the bias magnetic field is set to be equal to or more than the magnetic field intensity causing the magnetic saturation of the magnetoresistance element 51, which causes the external magnetic field to be higher than the bias magnetic field and also the free layer 51q to saturate quickly, the external magnetic field increases or decreases stepwise with respect to the magnetoresistance ΔR.

The magnetoresistance elements 51 disposed in the at least two blocks among the plurality of blocks may have the free layers 51q to which the bias magnetic field is applied. In addition, the magnetoresistance elements 51 disposed in the at least two blocks among the plurality of blocks may have the free layers 51q to which no bias magnetic field is applied. Furthermore, the blocks in which the magnetoresistance elements 51 having the free layers 51q to which no bias magnetic field is applied are disposed among the plurality of blocks may be arranged far from the conductor 24 (that is, at the location in which a low magnetic field is applied) relative to the blocks in which the magnetoresistance elements 51 having the free layers to which the bias magnetic field is applied are disposed.

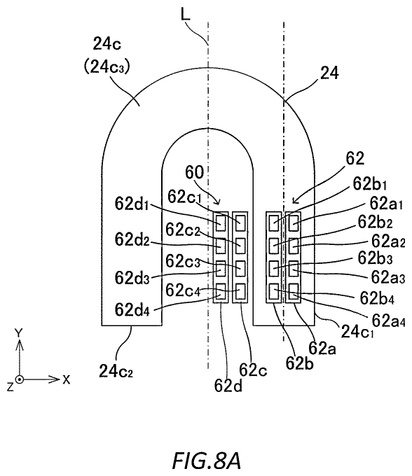

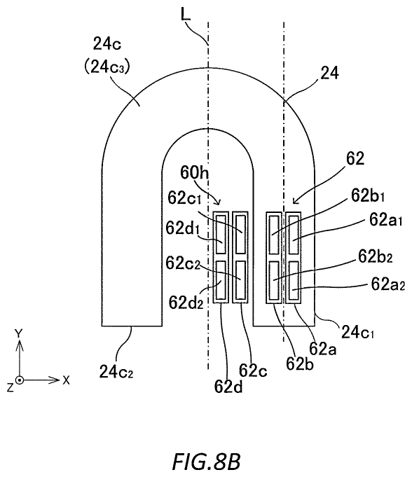

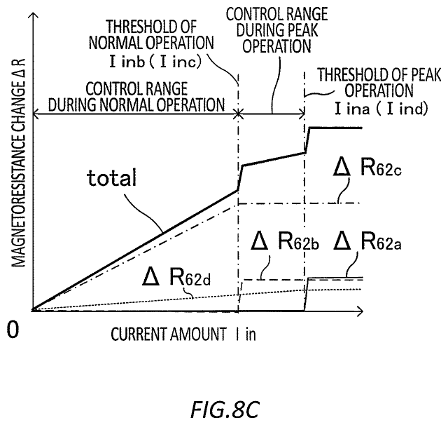

FIG. 8A illustrates the block arrangement of the magnetoresistance elements 51 constituting the current sensor 110 with a dual linearity, in which the threshold of the overcurrent detection changes according to the energization amount, using the full bridge magnetic sensor 60. In the magnetic sensor 60 of the present example, the plurality of blocks arranged on the substrate 61 (not shown in FIG. 8A) further include two extension blocks, that is, the third block 62c and the fourth block 62d, in addition to the first block 62a and the second block 62b illustrated in FIG. 2A. However, four blocks where the magnetoresistance elements 51 forming each of the magneto-electric conversion units 62, 63 are disposed are arranged in a symmetrical manner with respect to the reference line L. Thus, only four blocks 62a to 62d in the magneto-electric conversion unit 62 are illustrated and four blocks in the magneto-electric conversion unit 63 are not shown.

As with the above description, each of the first to fourth blocks 62a to 62d includes four subblocks 62a₁ to 62a₄, 62b₁ to 62b₄, 62c₁ to 62c₄, 62d₁ to 62d₄. Furthermore, on one surface of the substrate 61, a plurality of wires (not shown) are laid, which electrically connect the plurality of blocks 62a, 62b, 62c, 62d or the plurality of subblocks 62a₁ to 62a₄, 62b₁ to 62b₄, 62c₁ to 62c₄, 62d₁ to 62d₄ therein. As with the magneto-electric conversion unit 62, each of the plurality of blocks in the magneto-electric conversion unit 63 also includes four subblocks and is provided with a plurality of wires electrically connecting them.

For each of the plurality of subblocks 62a₁ to 62a₄, 62b₁ to 62b₄, 62c₁ to 62c₄, 62d₁ to 62d₄, the plurality of magnetoresistance elements 51 are connected in series by the electrode pieces 52, 53 to form a part of the resistor sides R1 to R4 and these resistor sides R1 to R4 are assembled into the Wheatstone bridge circuit (see FIG. 3).

The magnetic sensing directions of the magnetoresistance elements 51 disposed in each of the subblocks 62a₁ to 62a₄, 62b₁ to 62b₄, 62c₁ to 62c₄, 62d₁ to 62d₄ of each of the blocks 62a to 62d are the same as those of the magnetic sensors 60, 60h (see FIG. 7A and FIG. 7B) constituting the above-described quadruple linear current sensor 110. However, the magnetoresistance elements 51 disposed in the first block 62a and the second block 62b (the subblocks 62a₁ to 62a₄, 62b₁ to 62b₄) have the free layers 51q to which the bias magnetic field is applied. Herein, the bias magnetic fields of the magnetoresistance element 51 in the first block 62a are higher than the bias magnetic fields of the magnetoresistance element 51 in the second block 62b. In addition, any of the bias magnetic fields are approximately equal to the magnetic field intensity causing the magnetoresistance to saturate. The magnetoresistance elements 51 disposed in the third block 62c and the fourth block 62d (the subblocks 62c₁ to 62c₄, 62d₁ to 62d₄) have the free layer 51q to which no bias magnetic field is applied.

The first block 62a (the subblocks 62a₁ to 62a₄) and the second block 62b (the subblocks 62b₁ to 62b₄) are arranged on the arm 24c₁ and positioned on the +X side and the −X side of the arm center line, respectively. In this way, the magnetic field Bx with an approximately highest intensity generated by the to-be-measured current energizing the conductor 24 is applied to the magnetoresistance elements 51 of each of the first block 62a and the second block 62b. The third block 62c (the subblocks 62c₁ to 62c₄) and the fourth block 62d (the subblocks 62d₁ to 62d₄) are positioned between the two arms 24c₁, 24c₂ and on the side of the inner side of the arm 24c₁ and on the side of reference axis L, respectively. In this way, the magnetic field Bx with a relatively low and lowest intensity generated by the to-be-measured current energizing the conductor 24 is applied to the magnetoresistance elements 51 of each of the third block 62c and the fourth block 62d.

FIG. 8B illustrates the block arrangement of the magnetoresistance elements 51 constituting the current sensor 110 with a dual linearity, in which the threshold of the overcurrent detection changes according to the energization amount, using the half-bridge magnetic sensor 60h. In the magnetic sensor 60h of the present example, the plurality of blocks arranged on the substrate 61 (not shown in FIG. 8B) further include two extension blocks, that is, the third block 62c and the fourth block 62d, in addition to the first block 62a and the second block 62b illustrated in FIG. 5A. However, four blocks where the magnetoresistance elements 51 forming each of the magneto-electric conversion units 62, 63 are disposed are arranged in a symmetrical manner with respect to the reference line L. Thus, only four blocks 62a to 62d in the magneto-electric conversion unit 62 are illustrated and four blocks in the magneto-electric conversion unit 63 are not shown.

The first to fourth blocks 62a to 62d include the two subblocks 62a₁, 62a₂, 62b₁, 62b₂, 62c₁, 62c₂, 62d₁, 62d₂, respectively. Furthermore, on one surface of the substrate 61, a plurality of wires (not shown) are laid, which electrically connect the plurality of blocks 62a, 62b, 62c, 62d or the plurality of subblocks 62a₁, 62a₂, 62b₁, 62b₂, 62c₁, 62c₂, 62d₁, 62d₂ therein. As with the magneto-electric conversion unit 62, each of the plurality of blocks in the magneto-electric conversion unit 63 also includes two subblocks and is provided with a plurality of wires to electrically connect them.

For each of the plurality of subblocks 62a₁, 62a₂, 62b₁, 62b₂, 62c₁, 62c₂, 62d₁, 62d₂, the plurality of magnetoresistance elements 51 are connected in series by the electrode pieces 52, 53 to form a part of the resistor sides R1, R2 and these resistor sides R1, R2 are assembled into the half-bridge circuit (see FIG. 5B).

The magnetic sensing directions of the magnetoresistance elements 51 disposed in each subblocks 62a₁, 62a₂, 62b₁, 62b₂, 62c₁, 62c₂, 62d₁, 62d₂ of each block 62a to 62d are the same as those of the magnetic sensors 60, 60h (see FIG. 7A and FIG. 7B) constituting the above-described quadruple linear current sensor 110. However, the magnetoresistance elements 51 disposed in the first block 62a and the second block 62b (the subblocks 62a₁, 62a₂, 62b₁, 62b₂) have the free layers 51q to which the bias magnetic field is applied. Herein, the bias magnetic fields of the magnetoresistance element 51 in the first block 62a are higher than the bias magnetic fields of the magnetoresistance element 51 in the second block 62b. In addition, any of the bias magnetic fields are approximately equal to the magnetic field intensity causing the magnetoresistance to saturate. The magnetoresistance elements 51 disposed in the third block 62c and the fourth block 62d (the subblocks 62c₁, 62c₂, 62d₁, 62d₂) have the free layer 51q to which no bias magnetic field is applied.

The first block 62a (the subblocks 62a₁ to 62a₂) and the second block 62b (the subblocks 62b₁ to 62b₂) are arranged on the arm 24c₁ and positioned on the +X side and the −X side of the arm center line, respectively. In this way, the magnetic field Bx with an approximately highest intensity generated by the to-be-measured current energizing the conductor 24 is applied to the magnetoresistance elements 51 of each of the first block 62a and the second block 62b. The third block 62c (the subblocks 62c₁, 62c₂) and the fourth block 62d (the subblocks 62d₁, 62d₂) are positioned between the two arms 24c₁, 24c₂ and on the side of the inner side of the arm 24c₁ and on the side of reference axis L, respectively. In this way, the magnetic field Bx with a relatively low and lowest intensity generated by the to-be-measured current energizing the conductor 24 is applied to the magnetoresistance elements 51 of each of the third block 62c and the fourth block 62d.

FIG. 8C illustrates the magnetoresistance change ΔR of the magnetoresistance elements 51 of the four blocks 62a to 62d of the magnetic sensor 60 and each of the resistor sides R1 to R4 or R1, R2 in FIG. 8A and the magnetic sensor 60h in FIG. 8B with respect to the energization amount of the conductor 24. The magnetoresistance elements 51 included in the first block 62a (the subblocks 62a₁ to 62a₄ or 62a₁ to 62a₂), to which the magnetic field Bx with an approximately highest intensity generated by the to-be-measured current energizing the conductor 24 is applied, exhibit the magnetoresistance ΔR₆₂ₐ that quickly rises and reaches the magnetic saturation when the current amount exceeds the current amount Iina that generates the magnetic field with the intensity offsetting a relatively high bias magnetic field. The magnetoresistance elements 51 included in the second block 62b (the subblocks 62b₁ to 62b₄ or 62b₁ to 62b₂), to which the magnetic field Bx with an approximately highest intensity generated by the to-be-measured current is applied, exhibit the magnetoresistance ΔR_{62b} that quickly rises and reaches the magnetic saturation when the current amount exceeds the current amount Iinb (<Iina) that generate the magnetic fields with an intensity offsetting a relatively low bias magnetic field. The magnetoresistance elements 51 included in the third block 62c (the subblocks 62c₁ to 62c₄ or 62c₁ to 62c₂), to which the magnetic field Bx with a relatively low intensity generated by the to-be-measured current is applied, have a relatively low sensitivity with respect to the current amount Iin and exhibit the magnetoresistance ΔR_{62c} that reaches the magnetic saturation at a low current amount Iinc (=Iinb) or more. The magnetoresistance elements 51 included in the fourth block 62d (the subblocks 62d₁ to 62d₄ or 62d₁ to 62d₂), to which the magnetic field Bx with the lowest intensity generated by the to-be-measured current is applied, have the lowest sensitivity with respect to the current amount Iin (even lower than the magnetoresistance ΔR_{62c}) and exhibit the magnetoresistance ΔR_{62d} that reaches the magnetic saturation at a high current amount Iind (=Iina>Iinb) or more.

The magnetoresistance change ΔR (total) for each of the resistor sides R1 to R4 or R1, R2 is given by a linear sum of the magnetoresistances ΔR₆₂ₐ, ΔR_{62b}, ΔR_{62c}, ΔR_{62d} of the magnetoresistance elements 51 in the four blocks 62a to 62d. The magnetoresistance change ΔR exhibits dual linearity in which, with respect to the to-be-measured current Iin, it increases with the highest sensitivity (that is, with the largest slope) in the range of the current amounts 0 to Iinb, quickly increases at the current amount Iinb, increases with a low sensitivity (a small slope) in the range of the current amounts Iinb to Iina, quickly increases at the current amount Iina, and reaches the magnetic saturation at the current amount Iina or more. Note that the sensitivity in the range of the current amounts 0 to Iinb and Iinb to Iina can be adjusted by the position of the blocks 62c, 62d on the substrate 61 in the X axis direction.

Herein, it is assumed that the range of the current amounts 0 to Iinb (=Iinc) is the range during the normal operation, the current amount Iinb is the threshold for the normal operation, the current amounts Iinb to Iina (=Iind) is the range during the peak operation, and the current amount Iina is the threshold for the peak operation. The thresholds Iinb, Iina of the overcurrent detection change according to the energization amount Iin so that the current amount Iin can be detected with a high sensitivity within the range of a low magnetoresistance change during the normal operation and the current amount Iin can be detected with a low sensitivity in the range of a high magnetoresistance change during the peak operation in which the threshold Iinb of the normal operation is exceeded. In addition, the magnetoresistance change ΔR quickly increases at the current amounts Iinb, Iina so that the normal operation, the peak operation, or a higher current range can be easily detected.

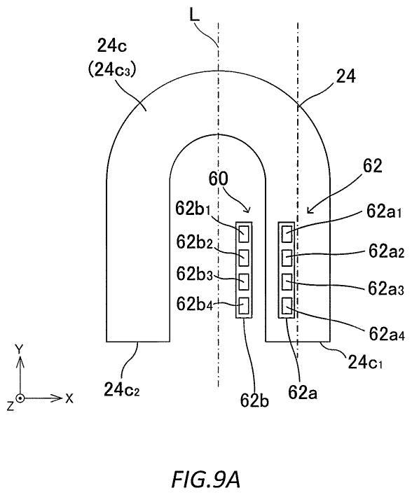

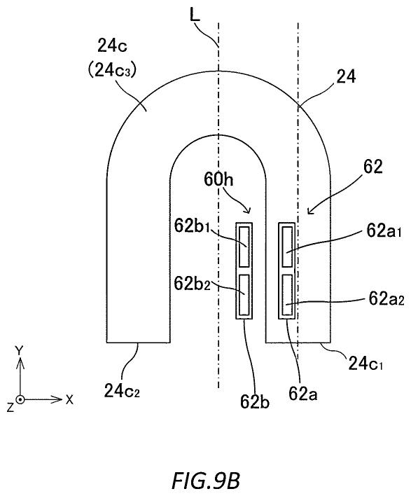

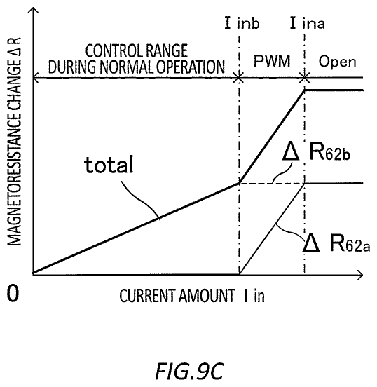

FIG. 9A illustrates the block arrangement of the magnetoresistance elements 51 constituting the current sensor 110 with a multi-linearity, having the sensitivity that changes according to the degree of the overcurrent, using the full bridge magnetic sensor 60. In the magnetic sensor 60 of the present example, the plurality of blocks arranged on the substrate 61 (not shown in FIG. 9A) includes a first block 62a and a second block 62b. However, two blocks where the magnetoresistance elements 51 forming each of the magneto-electric conversion units 62, 63 are disposed are arranged in a symmetrical manner with respect to the reference line L. Therefore, only two blocks 62a, 62b in the magneto-electric conversion unit 62 are illustrated and the two blocks in the magneto-electric conversion unit 63 are not illustrated. Note that, in the present example, the second block 62b is arranged on the side of the reference line L relative to the first block 62a. In this way, the magnetic sensor 60 can be constituted with a small chip area.

The first block 62a and the second block 62b include four subblocks 62a₁ to 62a₄, 62b₁ to 62b₄, respectively. Furthermore, on one surface of the substrate 61, a plurality of wires (not shown) are laid, which electrically connect the plurality of blocks 62a, 62b or the plurality of subblocks 62a₁ to 62a₄, 62b₁ to 62b₄ therein. As with the magneto-electric conversion unit 62, each of the plurality of blocks in the magneto-electric conversion unit 63 also includes four subblocks and is provided with a plurality of wires electrically connecting them.

For each of the plurality of subblocks 62a₁ to 62a₄, 62b₁ to 62b₄, the plurality of magnetoresistance elements 51 are connected in series by the electrode pieces 52, 53 to form a part of the resistor sides R1 to R4 and these resistor sides R1 to R4 are assembled into the Wheatstone bridge circuit (see FIG. 3).

The magnetic sensing directions of the magnetoresistance elements 51 disposed in each of the subblocks 62a₁ to 62a₄, 62b₁ to 62b₄ of each of the blocks 62a, 62b are the same as those of the magnetic sensors 60, 60h (see FIG. 7A and FIG. 7B) constituting the above-described quadruple linear current sensor 110. However, the magnetoresistance elements 51 disposed in the first block 62a (the subblocks 62a₁ to 62a₄) have the free layers 51q to which the bias magnetic field is applied. Herein, the bias magnetic field is sufficiently lower than the magnetic field intensity that causes the magnetoresistance element 51 to reach the magnetic saturation. The magnetoresistance elements 51 disposed in the second block 62b (the subblocks 62b₁ to 62b₄) has the free layer 51q to which no bias magnetic field is applied.

The first block 62a (the subblocks 62a₁ to 62a₄) is arranged near the center line on the arm 24c₁. In this way, the magnetic field Bx with an approximately highest intensity generated by the to-be-measured current energizing the conductor 24 is applied to the magnetoresistance element 51 in the first block 62a. The second block 62b (the subblocks 62b₁ to 62b₄) is positioned between the two arms 24c₁, 24c₂. In this way, the magnetic field Bx with a low intensity generated by the to-be-measured current energizing the conductor 24 is applied to the magnetoresistance element 51 in the second block 62b.

FIG. 9B illustrates the block arrangement of the magnetoresistance elements 51 constituting the current sensor 110 with a multi-linearity, having the sensitivity that changes according to the degree of the overcurrent, using the half-bridge magnetic sensor 60h. In the magnetic sensor 60h of the present example, the plurality of blocks arranged on the substrate 61 (not shown in FIG. 9B) include a first block 62a and a second block 62b. However, the two blocks in which the magnetoresistance element 51 forming each of the magneto-electric conversion units 62, 63 are arranged are disposed in a symmetrical manner with respect to the reference line L. Therefore, only two blocks 62a, 62b in the magneto-electric conversion unit 62 are illustrated and the two blocks in the magneto-electric conversion unit 63 are not illustrated. Note that, in the present example, the second block 62b is arranged on the side of the reference line L relative to the first block 62a. In this way, the magnetic sensor 60 can be constituted with a small chip area.

The first block 62a and the second block 62b include two subblocks 62a₁, 62a₂, 62b₁, 62b₂, respectively. Furthermore, on one surface of the substrate 61, a plurality of wires (not shown) are laid, which electrically connect the plurality of blocks 62a, 62b or the plurality of subblocks 62a₁, 62a₂, 62b₁, 62b₂ therein. As with the magneto-electric conversion unit 62, each of the plurality of blocks in the magneto-electric conversion unit 63 also includes two subblocks and is provided with a plurality of wires to electrically connect them.

For each of the plurality of subblocks 62a₁, 62a₂, 62b₁, 62b₂, the plurality of magnetoresistance elements 51 are connected in series by the electrode pieces 52, 53 to form a part of the resistor sides R1, R2 and these resistor sides R1, R2 are assembled into the half-bridge circuit (see FIG. 5B).

The magnetic sensing directions of the magnetoresistance elements 51 disposed in each of the subblocks 62a₁, 62a₂, 62b₁, 62b₂ of each of the blocks 62a to 62b are the same as those of the magnetic sensors 60, 60h (see FIG. 7A and FIG. 7B) constituting the above-described quadruple linear current sensor 110. However, the magnetoresistance elements 51 disposed in the first block 62a (the subblocks 62a₁, 62a₂) have the free layers 51q to which the bias magnetic field is applied. Herein, the bias magnetic field is sufficiently lower than the magnetic field intensity that causes the magnetoresistance element 51 to reach the magnetic saturation. The magnetoresistance elements 51 disposed in the second block 62b (the subblocks 62b₁, 62b₂) has the free layer 51q to which no bias magnetic field is applied. Herein, the magnetoresistance element 51 in the second block 62b reaches the magnetic saturation at the magnetic field intensity approximately equal to that of the bias magnetic field of the magnetoresistance element 51 in the first block 62a.

The first block 62a (the subblocks 62a₁, 62a₂) is arranged near the center line on the arm 24c₁. In this way, the magnetic field Bx with an approximately highest intensity generated by the to-be-measured current energizing the conductor 24 is applied to the magnetoresistance element 51 in the first block 62a. The second block 62b (the subblocks 62b₁, 62b₂) is positioned between the two arms 24c₁, 24c₂. In this way, the magnetic field Bx with a low intensity generated by the to-be-measured current energizing the conductor 24 is applied to the magnetoresistance element 51 in the second block 62b.

FIG. 9C illustrates the magnetoresistance change of the magnetoresistance elements 51 in the two blocks 62a. 62b of the magnetic sensor 60 in FIG. 9A and the magnetic sensor 60h in FIG. 9B and each of the resistor sides R1 to R4 or R1, R2, with respect to the energization amount of the conductor 24. The magnetoresistance elements 51 included in the first block 62a (the subblocks 62a₁ to 62a₄ or 62a₁ to 62a₂), to which the magnetic field Bx with an approximately highest intensity generated by the to-be-measured current energizing the conductor 24 is applied, exhibits the magnetoresistance ΔR₆₂ₐ that increases when the current amount Iin exceeds the current amount Iinb that generates the magnetic field with an intensity offsetting the bias magnetic field, and reaches the magnetic saturation at the current amount Iina or more, which is higher than the current amount Iinb. The magnetoresistance elements 51 included in the second block 62b (the subblock 62b₁ to 62b₄ or 62b₁ to 62b₂), to which a low magnetic field Bx generated by the to-be-measured current is applied, exhibits the magnetoresistance ΔR_{62b} that increases with a low sensitivity (lower than that of the magnetoresistance ΔR₆₂ₐ) with respect to the current amount Iin and reaches the magnetic saturation at the current amount Iinb or more.

The magnetoresistance change ΔR (total) of each of the resistor sides R1 to R4 or R1, R2 is given by the linear sum of the magnetoresistances ΔR₆₂ₐ, ΔR₆₂₂ of the magnetoresistance elements 51 in the two blocks 62a, 62b. The magnetoresistance change ΔR exhibits dual linearity in which, with respect to the to-be-measured current iin, it increases with a low sensitivity (that is, a small slope) in the range of the current amounts 0 to Iinb, increases with a high sensitivity (a large slope) in the range of the current amounts Iinb to Iina), and reaches the magnetic saturation at the current amount Iina or more. Note that the two sensitivities in the dual linearity can be adjusted by the position of the blocks 62a, 62b on the substrate 61 in the X axis direction.

Herein, it is assumed that the range of the current amounts 0 to Iinb is the range of normal control, the range of the current amounts Iinb to Iina is the range of PWM control, and the range of the current amounts Iina or more is the control range during severe failure. The sensitivity changes according to the degree of the overcurrent so that the current amount Iin is detected with low sensitivity during normal operation, the current amount Iin is detected with high sensitivity for PWM control of the switch of the power conversion circuit, for example, when the current amount Iin exceeds the threshold Iinb, and the switch is released when the current amount Iin exceeds the threshold Iina, which is determined to be a severe failure, while the magnetoresistance of the magnetoresistance element 51 is saturated since no current measurement is required in this range. With high sensitivity in the range from the current amounts Iinb to Iina, fine PWM control is possible to prevent the current amount from exceeding Iina to cause severe failure.

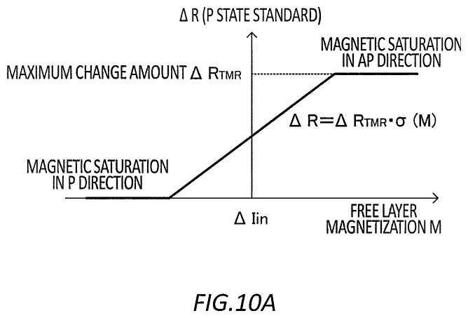

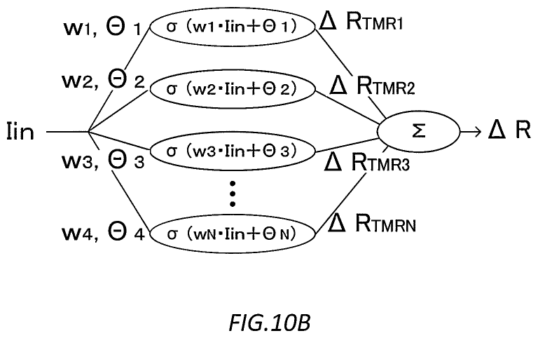

FIG. 10A illustrates the behavior of the magnetoresistance change ΔR of the magnetoresistance element 51 in one block or subblock with respect to the magnetization M of the free layer 51q. The magnetoresistance change ΔR of the magnetoresistance elements 51 exhibits the behavior in which it does not vary until the magnetizations of the free layer 51q and the fixed layer 51o become parallel (the P direction) to each other and zero and the magnetization M of the free layer exceeds the intensity that offsets the bias magnetic field applied to the free layer 51q, linearly increases with respect to the magnetization M once the intensity is exceeded, and reaches the magnetic saturation with the orientations of the magnetizations of the free layer 51q and the fixed layer 51o being anti-parallel (the AP direction) to each other as the magnetization M further increases. The magnetoresistance during saturation is described as the saturation resistance ΔR_{TMR}. The center of variation in the magnetoresistance is described as the shift amount ΔIin. The behavior of the magnetoresistance change ΔR can be represented by using a sigmoid function a (M) (->1 for M->+∞, 0 for M->−∞).

FIG. 10B illustrates a general expression of the magnetoresistance change ΔR of each of the resistor sides R1 to R4. The magnetoresistance ΔR of each of the resistor sides R1 to R4 can be represented as the linear sum of the magnetoresistances of the magnetoresistance elements 51 in a plurality of blocks k: ΔR=τₖΔR_{TMRk}·σ(Mₖ). Herein, the magnetization induced in the magnetoresistance element 51 in each block k with respect to the to-be-measured current Iin energizing the conductor 24 is given as Mₖ=wₖ·Iin+θₖ, wherein k is the index representing the plurality of blocks, wₖ is the linear coefficient with respect to the current amount Iin (the product of the magnetic susceptibility χ and the magnetoelectric conversion coefficient K defined according to the position x of the block k, that is, the magnetic field applied to the magnetoresistance element 51 when unit current flows through the conductor 24), and θₖ is the coefficient determined by the bias magnetic field applied to the free layer 51q (and the product of the bias magnetic field and the magnetic susceptibility χ). The saturation resistance ΔR_{TMRk} can be adjusted by a TMR ratio and a zero magnetic field resistance (the number of series of the magnetoresistance elements 51 in the block, the cross-sectional area of the magnetoresistance elements 51, the film thickness of the tunnel layer 51p, and the like). The linear coefficient wₖ can be adjusted by the magnetic susceptibility χ of the free layer and the locations of the plurality of blocks k on the conductor 24. Furthermore, the axis for easy magnetization may be adjusted by designing the shape of the free layer and the perpendicular magnetic anisotropy. The shift amount ΔIin can be adjusted by the intensity of the bias magnetic field. The adjustment can be made by arranging a hard magnetic material near the free layer 51q, or bonding an antiferromagnetic material (IrMn, PtMn, manganese nitride MnₓN_{y}, nickel oxide NiₓO_{y}, or the like) or a stack structure of a ferromagnetic material/a non-ferromagnetic material ([Co/Pt]n, [Co/Pd]n, or the like) to the free layer 51q. Therefore, the magnetoresistance change exhibiting an arbitrary behavior can be achieved by designing the ΔR_{TMRk}. wₖ, θₖ of the magnetoresistance element 51 for each of the plurality of blocks k.

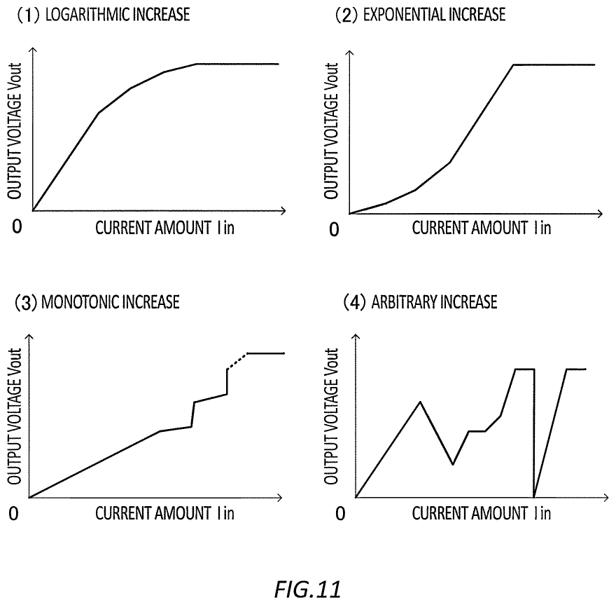

FIG. 11 illustrates four aspects of the change in the output voltage Vout of the current sensor 110 (that is, the magnetoresistance change ΔR of the magnetic sensors 60, 60h) with respect to the energization amount. (1) illustrates the logarithmic increase in which the output voltage Vout increases as the current amount Iin increases (dVout/dIin>0) and, however, the slope gradually becomes gentler (d²Vout/dIin²<0) to reach the saturation. (2) illustrates the exponential increase in which the output voltage Vout increases as the current amount Iin increases (dVout/dIin>0), and, however, the slope gradually becomes larger (d²Vout/dIin²>0) and reaches the saturation once the threshold is exceeded. (3) illustrates the monotonic increase in which the output voltage Vout increases as the current amount Iin increases (dVout/dIin>0), and, however, the slope becomes larger or smaller (d²Vout/dIin² is arbitrary) each time the plurality of thresholds are exceeded, and reaches the saturation once the threshold is exceeded. (4) illustrates the arbitrary increase in which the output voltage Vout increases or decreases and the slope becomes larger or smaller (dVout/dIin and d²Vout/dIin² are arbitrary) each time the current amount Iin increases to exceed the plurality of thresholds, and reaches the saturation once the last threshold is exceeded.

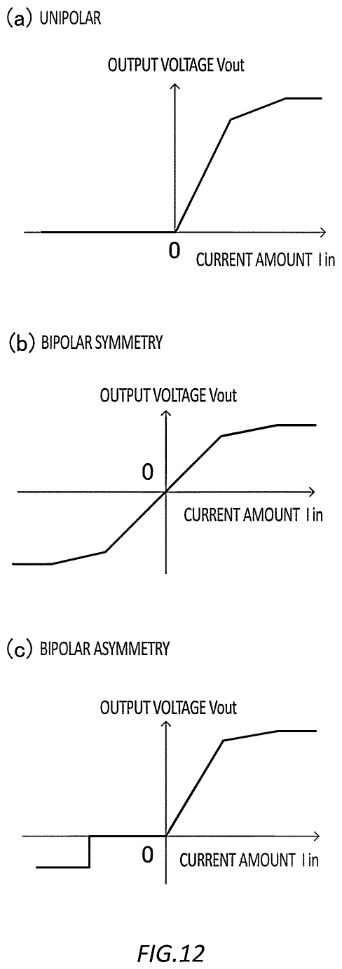

FIG. 12 illustrates the polarity of the output voltage Vout of the current sensor 110 (that is, the magnetoresistance change ΔR of the magnetic sensors 60, 60h) with respect to the energization amount. (a) illustrates a unipolar property in which the output voltage Vout varies with respect to the positive current amount Iin and does not vary with respect to the negative current amount Iin. (b) illustrates a bipolar symmetrical property (Vout (−Iin)=−Vout (Iin)) in which the output voltage Vout varies in a symmetrical manner with respect to the positive and negative current amount Iin. (c) illustrates a bipolar asymmetrical property in which the output voltage Vout varies with respect to the positive or negative current amount Iin and the aspect of the change is asymmetrical with respect to the positive and negative current amounts Iin.

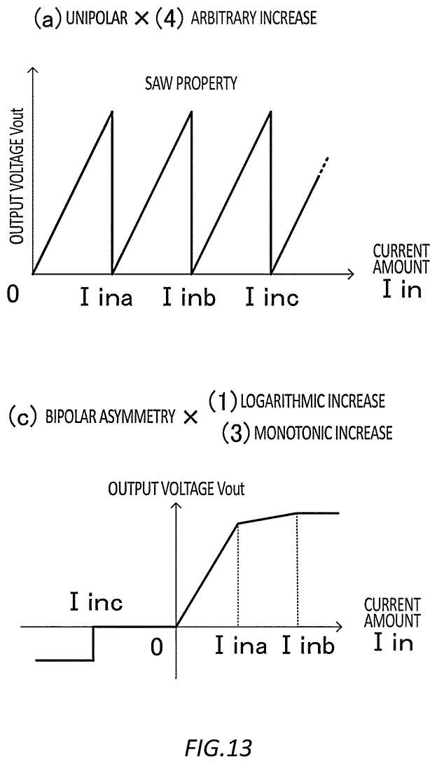

FIG. 13 illustrates an example of a combination of the aspects of the change in the output voltage Vout of the magnetic sensors 60, 60h illustrated in FIG. 11 and the polarity illustrated in FIG. 12.

The upper side illustrates an example of a combination of the (a) unipolar property and (4) arbitrary increase, that is, a saw property. In this example, the output voltage Vout only varies with respect to the positive current amount Iin, linearly increases as the current amount Iin increases, becomes zero once the current amount Iin exceeds the thresholds Iina, Iinb, and Iinc, and then linearly increases again. The magnetic sensors 60, 60h having such a saw property of the output voltage is used in combination with another current sensor with a large range and low precision so that the position of the sawtooth in the saw property of the magnetic sensors 60, 60h is defined by roughly measuring the current amount by another current sensor and the current amount Iin can be precisely determined by the output voltage Vout of the magnetic sensors 60, 60h in the range of the sawtooth.

The lower side illustrates an example of a combination of the (c) bipolar asymmetrical property and the (1) logarithmic increase and the (3) monotonic increase. In this example, the output voltage Vout linearly increases as the current amount Iin increases in the positive direction, however, the slope becomes gentler once the current amount Iin exceeds the threshold Iina, reaches saturation once the threshold Iinb is exceeded, and increases stepwise in the negative direction to reach saturation once the current amount Iin increases in the negative direction to exceed the threshold Iinc. If the coil current of a buck converter circuit operating in, for example, a continuous energization mode is measured by using the magnetic sensors 60, 60h having such a property, the determination of normal or abnormal can be made by precisely measuring the positive current amount and also detecting the reverse current generated during a failure because the polarity of the current during a normal situation is defined.

The behaviors of the magnetic sensors 60, 60h with respect to the current amount Iin have 20 types of aspects in total including the combination of the (a) unipolar property and the (1) to (4) increase properties (four types), the combination of the (b) bipolar symmetrical property and the (1) to (4) increase properties (four types), and the combination of the (c) bipolar asymmetrical property and the (1) to (4) increase properties (12 types). The six types of the basic properties I_{±}, II_{±}, III_{±} of the magnetoresistance element 51 for constituting these 20 types of aspects are defined. These basic properties can be achieved by defining the block arrangement (the orientation of the magnetic field generated by the to-be-measured current), the magnetic field detection direction (the magnetic sensing direction), and the direction of the bias magnetic field for the magnetoresistance elements in each block.

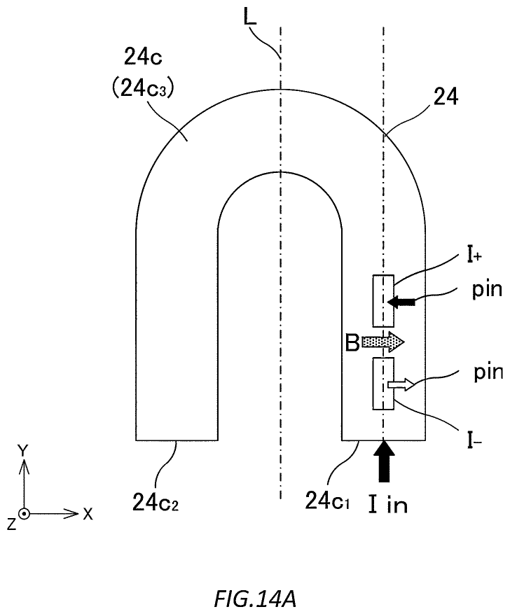

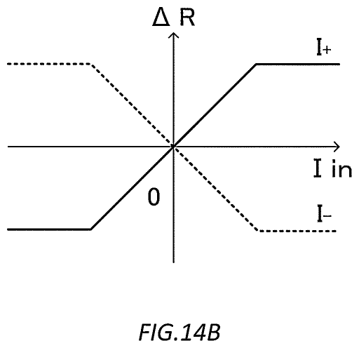

FIG. 14A illustrates an example of the block arrangement, the magnetic field detection direction, and the direction of the bias magnetic field for the magnetoresistance element 51 having the first type I_{±} of the basic property. Note that the block of the magnetoresistance elements 51 can be arranged on the substrate 61 in a symmetrical manner with respect to the reference line L, and the magnetoresistance elements 51 arranged in the block can be configured in a symmetrical manner with respect to the reference line L, that is, the magneto-electric conversion units 62, 63 can be configured in a symmetrical manner. Herein, only the basic property of the magnetoresistance element 51 arranged on the +X side with respect to the reference line L is considered.

In the present example, the block of the magnetoresistance elements 51 is positioned on the top surface of the substrate 61 on the +X side with respect to the reference line L, for example, on the arm 24c₁ of the conductor 24. When the to-be-measured current Iin is input to the arm 24c₁, the magnetic field B in the +X direction is applied to the magnetoresistance elements 51 in this block. The magnetoresistance element 51 of type I_{±} has magnetization (pin) of a stationary phase fixed to be anti-parallel (−X direction) to the X magnetic field B and has no bias magnetic field applied. The magnetoresistance element 51 of type L has the magnetization (pin) of a stationary phase that is parallel (in the +X direction) to the X magnetic field B and has no bias magnetic field applied.

FIG. 14B illustrates the property of the magnetoresistance change ΔR with respect to the energization amount Iin, exhibited by the magnetoresistance element 51 of the first type I_{±}. The magnetoresistance change ΔR of the magnetoresistance element 51 of the type I_{±} (indicated with the solid line) exhibits the property in which, with the zero current being the variation reference due to no bias magnetic field being applied, it increases as the current amount Iin increases in the positive direction since the pin direction is anti-parallel to the magnetic field B, and reaches saturation at a larger current amount Iin, and also decreases (increases in the negative direction) as the current amount Iin increases in the negative direction, and reaches saturation at a larger negative current amount Iin. The magnetoresistance change ΔR of the magnetoresistance element 51 of type I₋ (indicated with the dotted line) exhibits the property in which, with the zero current being the variation reference due to no bias magnetic field being applied, it decreases (increases in the negative direction) as the current amount Iin increases in the positive direction since the pin direction is parallel to the magnetic field B, and reaches saturation at a larger current amount Iin, and also increases as the current amount Iin increases in the negative direction, and reaches saturation at the larger negative current amount Iin.

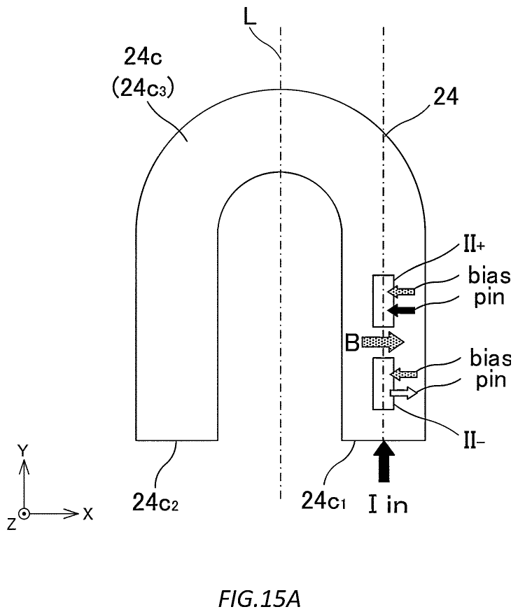

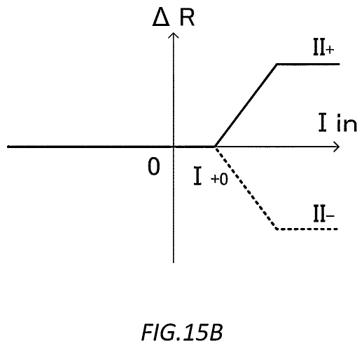

FIG. 15A illustrates an example of the block arrangement, the magnetic field detection direction, and the direction of the bias magnetic field for the magnetoresistance element 51 having the second type II_{±} of the basic property. The block of the magnetoresistance elements 51 is positioned on the top surface of the substrate 61 on the +X side with reference to the reference line L (in the present example, positioned on the arm 24c₁ of the conductor 24). When the to-be-measured current Iin is input to the arm 24c₁, the magnetic field B in the +X direction is applied to the magnetoresistance element 51 in this block. The magnetoresistance element 51 of type II₊ has magnetization (pin) of stationary phase fixed to be anti-parallel (−X direction) to the X magnetic field B and has the anti-parallel (−X direction) bias magnetic field applied. The magnetoresistance element 51 of type II₋ has magnetization (pin) of stationary phase parallel (+X direction) to the X magnetic field B and has the anti-parallel (−X direction) bias magnetic field applied.

FIG. 15B illustrates the property of the magnetoresistance change ΔR with respect to the energization amount Iin, exhibited by the magnetoresistance element 51 of the second type II_{±}. The magnetoresistance change ΔR of the magnetoresistance element 51 of type II₊ (indicated with the solid line) exhibits a property in which it varies at the current amount Iin of the positive current I₊₀ or more with the anti-parallel bias magnetic field being applied, increases as the current amount Iin increases in the positive direction since the pin direction is anti-parallel to the magnetic field B, and reaches saturation at the larger current amount Iin. The magnetoresistance change ΔR of the magnetoresistance element 51 of type II₋ (indicated with the dotted line) exhibits a property in which it varies at the current amount Iin of the positive current I₊₀ or more with the anti-parallel bias magnetic field being applied, decreases (increases in the negative direction) as the current amount Iin increases in the positive direction since the pin direction is parallel to the magnetic field B, and reaches saturation at the larger current amount Iin.

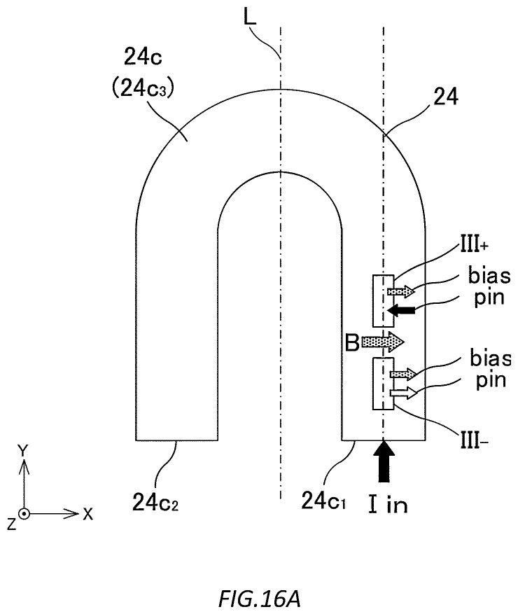

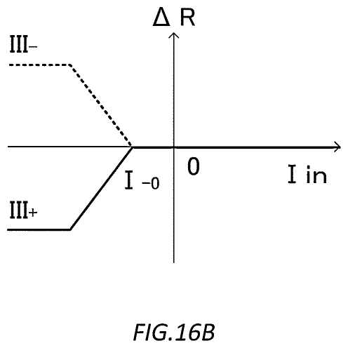

FIG. 16A illustrates an example of the block arrangement, the magnetic field detection direction, and the direction of the bias magnetic field of the magnetoresistance element 51 having the basic property of the third type III_{±}. The block of the magnetoresistance elements 51 is positioned on the top surface of the substrate 61 on the +X side with reference to the reference line L (in the present example, positioned on the arm 24c₁ of the conductor 24). When the to-be-measured current Iin is input to the arm 24c₁, the magnetic field B in the +X direction is applied to the magnetoresistance element 51 in this block. The magnetoresistance element 51 of type III₊ has magnetization (pin) of stationary phase fixed to be parallel (+X direction) to the X magnetic field B and has the anti-parallel (−X direction) bias magnetic field applied. The magnetoresistance element 51 of type III₋ has magnetization (pin) of stationary phase that is parallel (+X direction) to the X magnetic field B and has a parallel (+X direction) bias magnetic field applied.

FIG. 16B illustrates the property of the magnetoresistance change ΔR with respect to the energization amount Iin, exhibited by the magnetoresistance element 51 of the third type III_{±}. The magnetoresistance change ΔR of the magnetoresistance element 51 of type III₊ (indicated with the solid line) exhibits a property in which it varies at the current amount Iin of the negative current I₋₀ or less with the parallel bias magnetic field being applied, decreases (increases in the negative direction) as the current amount Iin increases in the negative direction since the pin direction is anti-parallel to the magnetic field B, and reaches saturation at the larger current amount Iin. The magnetoresistance change ΔR of the magnetoresistance element 51 of type III₋ (indicated with the dotted line) exhibits a property in which it varies at the current amount Iin of the negative current I₋₀ or less with the parallel bias magnetic field being applied, increases as the current amount Iin increases in the negative direction since the pin direction is parallel to the magnetic field B, and reaches saturation at the larger current amount Iin.

Three types I_{±}, II_{±}, III_{±} of the magnetoresistance elements 51 are used to reproduce the behavior of the magnetoresistance change ΔR with respect to the current amount Iin of the magnetic sensors 60, 60h (that is, the output voltage Vout (∝ΔR)), for example, four types of behaviors combining the (b) bipolar symmetrical property and the (1) to (4) increase properties, four types of behaviors combining the (a) unipolar property and the (1) to (4) increase properties, and two types of behaviors combining the (c) bipolar asymmetrical property and the (3) increase property.

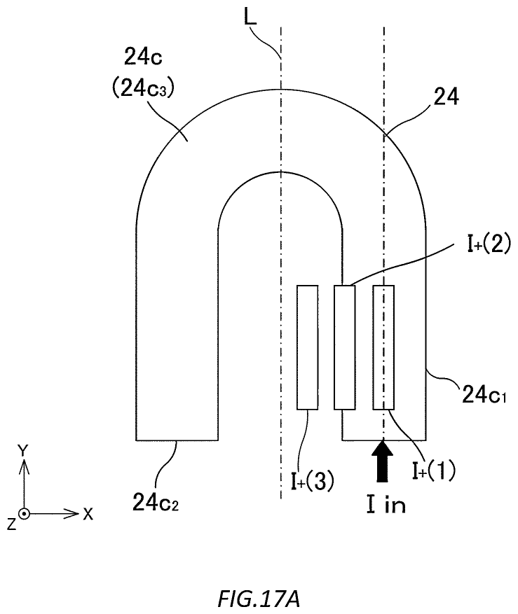

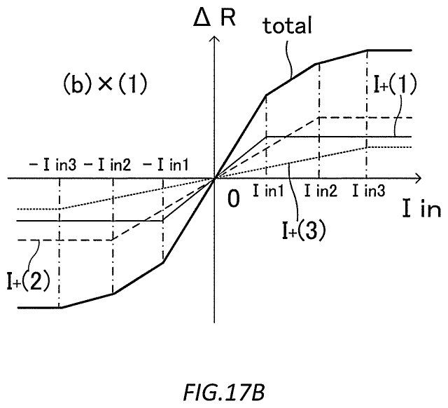

FIG. 17A illustrates the type and block arrangement of the magnetoresistance element 51 exhibiting the (b) bipolar symmetry and the (1) logarithmic increase property. Note that the blocks of the magnetoresistance elements 51 can be arranged on the substrate 61 in a symmetrical manner with respect to the reference line L, and the magnetoresistance elements 51 arranged in the blocks can be configured in a symmetrical manner with respect to the reference line L, that is, the magneto-electric conversion units 62, 63 can be configured in a symmetrical manner. Herein, only the type and block arrangement of the magnetoresistance element 51 arranged on the +X side with respect to the reference line L is considered. In addition, the resistor sides R1 to R4 in the full bridge magnetic sensor 60 or the resistor sides R1 to R2 in the half-bridge magnetic sensor 60h can be formed by appropriately connecting the magnetoresistance elements 51 in the subblock included in each block.

In the present example, three blocks in which the magnetoresistance elements 51 of types I₊(1) to I₊(3) are each disposed are arrayed on the top surface of the substrate 61 in the X axis direction. The magnetoresistance elements 51 of types I₊(1) to I₊(3) reach magnetic saturation at the current amounts Iin1, Iin2, Iin3 (Iin1<Iin2<Iin3) or more, respectively. The block of the magnetoresistance elements 51 of type I₊(1) is positioned on the center line of the arm 24c₁ of the conductor 24 and the magnetic field with the highest intensity generated by the to-be-measured current Iin energizing the conductor 24 is applied to those magnetoresistance elements 51; the block of the magnetoresistance elements 51 of type I₊(2) is positioned on the inner side of the arm 24c₁ and the magnetic field with a medium intensity generated by the to-be-measured current Iin is applied to those magnetoresistance elements 51; and the block of the magnetoresistance elements 51 of type I₊(3) is positioned between the arms 24c₁, 24c₂ and the magnetic field with the lowest intensity generated by the to-be-measured current Iin is applied to those magnetoresistance element 51.

FIG. 17B illustrates the property of the magnetoresistance change ΔR with respect to the energization amount Iin exhibited by each block of the magnetoresistance elements 51 in FIG. 17A and the magnetic sensors 60, 60h (each of the resistor sides R1 to R4 or R1, R2). The magnetoresistance element 51 of type I₊(1) has the highest sensitivity with respect to the current amount Iin when the magnetic field with the highest intensity generated by the to-be-measured current Iin is applied thereto, and reaches the magnetic saturation at the current amount Iin or more. The magnetoresistance element 51 of type I₊(2) has a medium sensitivity with respect to the current amount Iin when the magnetic field with a medium intensity is applied thereto, and reaches the magnetic saturation at the current amount Iin2 (>Iin1) or more. The magnetoresistance element 51 of type I₊(3) has the lowest sensitivity with respect to the current amount Iin when the magnetic field with the lowest intensity is applied thereto, and reaches the magnetic saturation at the current amount Iin3 (>Iin2) or more.

The magnetoresistance change ΔR (total) of the magnetic sensors 60, 60h (each of the resistor sides R1 to R4 or R1, R2) is given by the linear sum of the magnetoresistances of the magnetoresistance elements 51 of three types: I₊(1) to I₊(3). Therefore, with respect to the positive to-be-measured current Iin, the magnetoresistance change ΔR increases with the highest sensitivity (that is, the largest slope) in the range of the current amounts 0 to Iin1, increases with a medium sensitivity (the medium slope) in the range of the current amounts Iin1 to Iin2, increases with the lowest sensitivity (the smallest slope) in the range of the current amounts Iin2 to Iin3, and reaches the magnetic saturation at the current amount Iin3 or more. In addition, with respect to the negative to-be-measured current Iin, the magnetoresistance change ΔR decreases (increases in the negative direction) with the highest sensitivity (that is, the largest slope) in the range of the current amounts 0 to −Iin1, decreases (increases in the negative direction) with a medium sensitivity (the medium slope) in the range of the current amounts −Iin1 to −Iin2, decreases (increases in the negative direction) with the lowest sensitivity (the smallest slope) in the range of the current amounts −Iin2 to −Iin3, and reaches the magnetic saturation at the current amount −Iin3 or less.

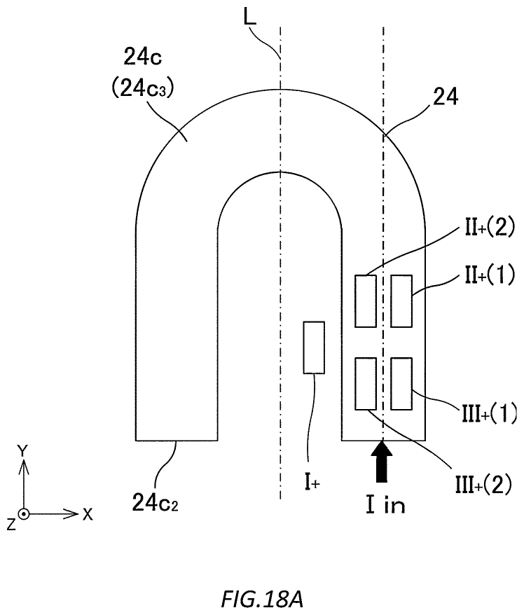

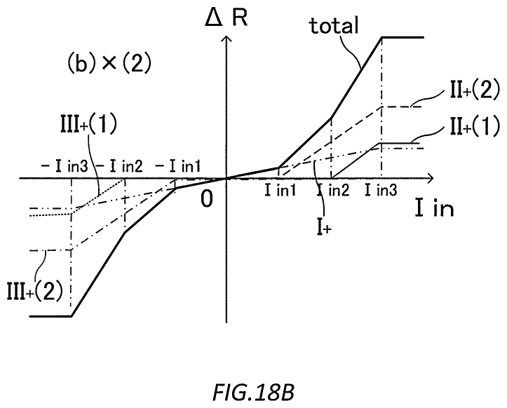

FIG. 18A illustrates the type and block arrangement of the magnetoresistance element 51 exhibiting the (b) bipolar symmetry and the (2) exponential increase property. In the present example, five blocks in which the magnetoresistance elements 51 of types I₊, II₊(1), II₊(2), III₊(1), III₊(2) are each disposed are arrayed on the top surface of the substrate 61. The block of the magnetoresistance elements 51 of type I₊ is positioned between the arms 24c₁, 24c₂ of the conductor 24 and the magnetic field with the lowest intensity generated by the to-be-measured current Iin is applied to those magnetoresistance elements 51. The block of the magnetoresistance elements 51 of types II₊(1), II₊(2) is positioned on the arm 24c₁, and the magnetic field with approximately the highest intensity generated by the to-be-measured current Iin is applied to those magnetoresistance elements 51. The magnetoresistances of the magnetoresistance elements 51 of types II₊(1), II₊(2), to which a relatively high or low bias magnetic field (referred to as a strong bias magnetic field and a weak bias magnetic field) is applied, vary with respect to the current amount Iin that is equal to or more than the current amounts Iin2, Iin1 (>Iin2), respectively, and reach the magnetic saturation at the current amount Iin3 or more. The block of the magnetoresistance elements 51 of types III₊(1), III₊(2) is positioned on the arm 24c₁, and the magnetic field with approximately the highest intensity generated by the to-be-measured current Iin is applied to those magnetoresistance elements 51. The magnetoresistances of the magnetoresistance elements 51 of types III₊(1), III₊(2), to which the strong bias magnetic field and the weak bias magnetic field are applied, vary with respect to the current amount Iin that is equal to or less than the current amounts −Iin2, −Iin1 (<−Iin2), respectively, and reach the magnetic saturation at the current amount −Iin3 or less.

FIG. 18B illustrates the property of the magnetoresistance change ΔR with respect to the energization amount Iin exhibited by each block of the magnetoresistance elements 51 in FIG. 18A and the magnetic sensors 60, 60h (each of the resistor sides R1 to R4 or R1, R2). The magnetoresistance element 51 of type I₊(1), to which the magnetic field with the lowest intensity generated by the to-be-measured current Iin is applied, has the lowest sensitivity with respect to the current amount Iin and reaches the magnetic saturation at the current amount Iin3 or more and at the current amount −Iin3 or less. The magnetoresistance element 51 of type II₊(1), to which the magnetic field with the highest intensity is applied, has the highest sensitivity with respect to the current amount Iin, has the magnetoresistance that varies at the current amount Iin2 or more, and reaches the magnetic saturation at the current amount Iin3 or more. The magnetoresistance element 51 of type II₊(2), to which the magnetic field with the highest intensity is applied, has the highest sensitivity with respect to the current amount Iin, has the magnetoresistance that varies at the current amount Iin1 (<Iin2) or more, and reaches the magnetic saturation at the current amount Iin3 or more. The magnetoresistance element 51 of type III₊(1), to which the magnetic field with the highest intensity is applied, has the highest sensitivity with respect to the current amount Iin, has the magnetoresistance that varies at the current amount −Iin2 or less, and reaches the magnetic saturation at the current amount −Iin3 or less. The magnetoresistance element 51 of type III₊(2), to which the magnetic field with the highest intensity is applied, has the highest sensitivity with respect to the current amount Iin, has the magnetoresistance that varies at the current amount −Iin1 (>−Iin2) or less, and reaches the magnetic saturation at the current amount −Iin3 or less.

The magnetoresistance change ΔR (total) of the magnetic sensors 60, 60h (each of the resistor sides R1 to R4 or R1, R2) is given by the linear sum of the magnetoresistances of the magnetoresistance elements 51 of five types: I₊, II₊(1), II₊(2), III₊(1), III₊(2). Therefore, with respect to the positive to-be-measured current Iin, the magnetoresistance change ΔR increases with the lowest sensitivity (that is, the smallest slope) in the range of the current amounts 0 to Iin1, increases with the medium sensitivity (the medium slope) in the range of the current amounts Iin1 to Iin2, increases with the highest sensitivity (the largest slope) in the range of the current amounts Iin2 to Iin3, and reaches the magnetic saturation at the current amount Iin3 or more. In addition, with respect to the negative to-be-measured current Iin, the magnetoresistance change ΔR decreases (increases in the negative direction) with the lowest sensitivity (that is, the smallest slope) in the range of the current amounts 0 to −Iin1, decreases (increases in the negative direction) with the medium sensitivity (the medium slope) in the range of the current amounts −Iin1 to −Iin2, decreases (increases in the negative direction) with the highest sensitivity (the largest slope) in the range of the current amounts −Iin2 to the −Iin3, and reaches the magnetic saturation at the current amount −Iin3 or less.

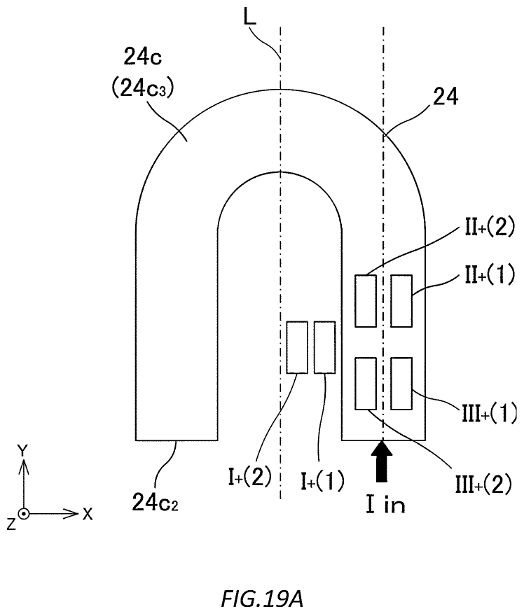

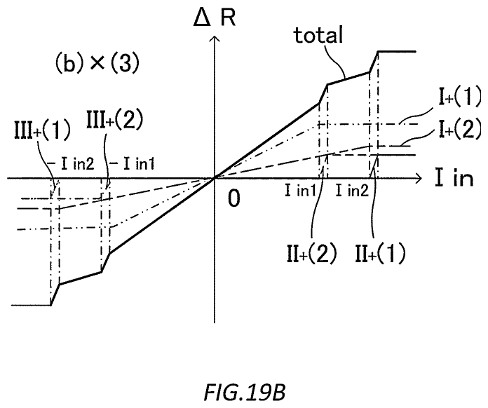

FIG. 19A illustrates the type and block arrangement of the magnetoresistance element 51 exhibiting the (b) bipolar symmetry and the (3) monotonic increase property. In the present example, six blocks in which the magnetoresistance elements 51 of types I₊(1), I₊(2), II₊(1), II₊(2), III₊(1), III₊(2) are each disposed are arrayed on the top surface of the substrate 61. The blocks of the magnetoresistance elements 51 of types I₊(1), I₊(2) are positioned on the side of the arm 24c₁ and the side of the reference axis L, respectively, between the arms 24c₁, 24c₂ of the conductor 24 and the magnetic field with a medium intensity and the lowest intensity generated by the to-be-measured current Iin are applied to those magnetoresistance elements 51, respectively. The magnetoresistances of the magnetoresistance elements 51 of types I₊(1), I₊(2) linearly vary with respect to the current amount Iin, reach the magnetic saturation at the current amounts Iin1, Iin2 or more, respectively, and reach the magnetic saturation at the current amounts Iin1, Iin2 or less, respectively. The block of the magnetoresistance elements 51 of types II₊(1), II₊(2) is positioned on the arm 24c₁, and the magnetic field with approximately the highest intensity generated by the to-be-measured current Iin is applied to those magnetoresistance elements 51. The magnetoresistances of the magnetoresistance elements 51 of types II₊(1), II₊(2), to which the strong bias magnetic field and the weak bias magnetic field are applied, increase approximately stepwise at the current amounts Iin2, Iin1 (<Iin2), respectively. The block of the magnetoresistance elements 51 of types III₊(1), III₊(2) is positioned on the arm 24c₁, and the magnetic field with approximately the highest intensity generated by the to-be-measured current Iin is applied to those magnetoresistance elements 51. The magnetoresistances of the magnetoresistance elements 51 of types III₊(1), III₊(2), to which the strong bias magnetic field and the weak bias magnetic field are applied, decrease (increase in the negative direction) approximately stepwise at the current amounts −Iin2, −Iin1 (>−Iin2), respectively.

FIG. 19B illustrates the property of the magnetoresistance change ΔR with respect to the energization amount Iin exhibited by each block of the magnetoresistance elements 51 in FIG. 19A and the magnetic sensors 60, 60h (each of the resistor sides R1 to R4 or R1, R2). The magnetoresistance elements 51 of types I₊(1), I₊(2), to which the magnetic fields with a medium intensity and the lowest intensity generated by the to-be-measured current Iin are applied, have low sensitivity and the lowest sensitivity with respect to the current amount Iin, respectively, reach the magnetic saturation at the current amounts Iin1, Iin2 or more, and reach the magnetic saturation at the current amounts −Iin1, −Iin2 or less, respectively. The magnetoresistance elements 51 of types II₊(1), II₊(2), to which the magnetic field with the highest intensity is applied, have the highest sensitivity with respect to the current amount Iin and have the magnetoresistances that increase approximately stepwise at the current amounts Iin2, Iin1 (<Iin2) or more, respectively, to reach the magnetic saturation. The magnetoresistance elements 51 of types III₊(1), III₊(2), to which the magnetic field with the highest intensity is applied, have the highest sensitivity with respect to the current amount Iin and have the magnetoresistances that decrease (increase in the negative direction) approximately stepwise at the current amounts −Iin2, −Iin1 (>−Iin2) or less, respectively, to reach the magnetic saturation.

The magnetoresistance change ΔR (total) of the magnetic sensors 60, 60h (each of the resistor sides R1 to R4 or R1, R2) is given by the linear sum of the magnetoresistances of the magnetoresistance elements 51 of six types: I₊(1), I₊(2), II₊(1), II₊(2), III₊(1), III₊(2). Therefore, to the positive to-be-measured current Iin, the magnetoresistance change ΔR increases with high sensitivity (that is, a large slope) in the range of the current amounts 0 to Iin1, increases approximately stepwise at the current amount Iin1, increases with low sensitivity (a small slope) in the range of the current amounts Iin1 to Iin2, and increases approximately stepwise at the current amount Iin2 to reach the magnetic saturation. In addition, to the negative to-be-measured current Iin, the magnetoresistance change ΔR decreases (increases in the negative direction) with high sensitivity (that is, a large slope) in the range of the current amounts 0 to −Iin1, decreases (increases in the negative direction) approximately stepwise at the current amount −Iin1, decreases (increases in the negative direction) with low sensitivity (a small slope) in the range of the current amounts −Iin1 to −Iin2, and decreases (increases in the negative direction) approximately stepwise at the current amount −Iin2 to reach the magnetic saturation.

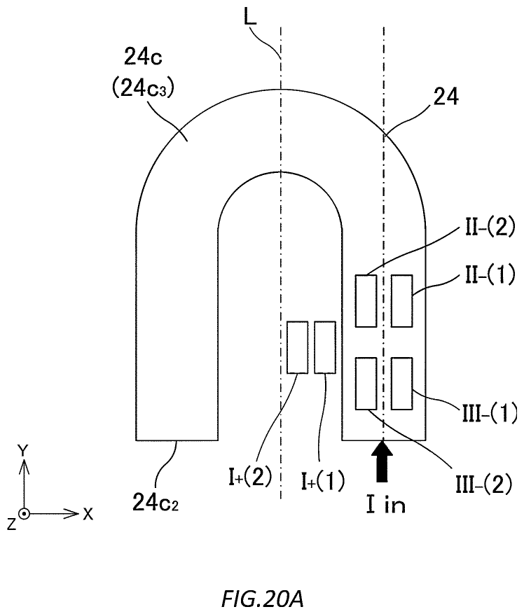

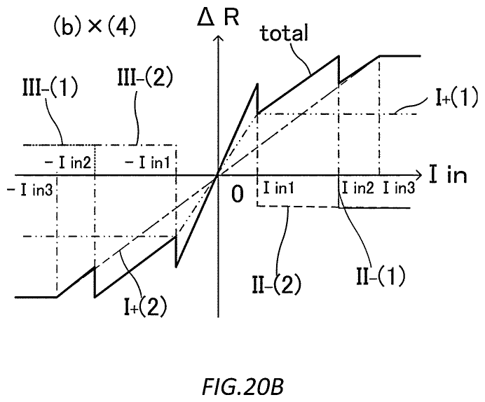

FIG. 20A illustrates the type and block arrangement of the magnetoresistance element 51 that exhibits the (b) bipolar symmetry and the (4) arbitrary increase property. In the present example, six blocks in which the magnetoresistance elements 51 of type I₊(1), I₊(2), II₋(1), II₋(2), III₋(1), III₋(2) are each disposed are arrayed on the top surface of the substrate 61. The blocks of the magnetoresistance elements 51 of types I₊(1), I₊(2) are positioned on the side of the arm 24c₁ and the side of the reference axis L, respectively, between the arms 24c₁, 24c₂ of the conductor 24 and the magnetic field with a medium intensity and the lowest intensity generated by the to-be-measured current Iin are applied to those magnetoresistance elements 51, respectively. The magnetoresistances of the magnetoresistance elements 51 of types II₋(1), II₋(2) linearly vary with respect to the current amount Iin, reach the magnetic saturation at the current amounts Iin1, Iin3 or more and also reach the magnetic saturation at the current amounts −Iin1, −Iin3 or less, respectively. The block of the magnetoresistance elements 51 of types II₋(1), II₋(2) is positioned on the arm 24c₁, and the magnetic field with an approximately highest intensity generated by the to-be-measured current Iin is applied to those magnetoresistance elements 51. The magnetoresistances of the magnetoresistance elements 51 of types II₋(1), II₋(2), to which the strong bias magnetic field and the weak bias magnetic field are applied, decrease (increase in the negative direction) stepwise at the current amounts Iin2, Iin1 (<Iin2), respectively. The block of the magnetoresistance elements 51 of types III₋(1), III₋(2) is positioned on the arm 24c₁, and the magnetic field with an approximately highest intensity generated by the to-be-measured current Iin is applied to those magnetoresistance elements 51. The magnetoresistances of the magnetoresistance elements 51 of types III₋(1), III₋(2), to which the strong bias magnetic field and the weak bias magnetic field are applied, increase stepwise at the current amounts −Iin2, −Iin1 (>−Iin2), respectively.

FIG. 20B illustrates the property of the magnetoresistance change ΔR with respect to the energization amount Iin exhibited by each block of the magnetoresistance elements 51 in FIG. 20A and the magnetic sensors 60, 60h (each of the resistor sides R1 to R4 or R1, R2). The magnetoresistance elements 51 of types I₊(1), I₊(2), to which the magnetic fields with medium intensity and the lowest intensity generated by the to-be-measured current Iin are applied, have low sensitivity and the lowest sensitivity with respect to the current amount Iin, respectively, reach the magnetic saturation at the current amounts Iin1, Iin3 or more, and reach the magnetic saturation at the current amounts −Iin1, −Iin3 or less, respectively. The magnetoresistance elements 51 of types II₋(1), II₋(2), to which the magnetic field with the highest intensity is applied, have the highest sensitivity with respect to the current amount Iin and have the magnetoresistances that decrease (increase in the negative direction) stepwise at the current amounts Iin2, Iin1 (<Iin2) or more, respectively, to reach the magnetic saturation. The magnetoresistance elements 51 of types III₋(1), III₋(2), to which the magnetic field with the highest intensity is applied, have the highest sensitivity with respect to the current amount Iin and have the magnetoresistances that increase stepwise at the current amounts −Iin2, −Iin1 (>−Iin2) or less, respectively, to reach the magnetic saturation.

The magnetoresistance change ΔR (total) of the magnetic sensors 60, 60h (each of the resistor sides R1 to R4 or R1, R2) is given by the linear sum of the magnetoresistances of the magnetoresistance elements 51 of six types: I₊(1), I₊(2), II₋(1), II₋(2), III₋(1), III₋(2). Therefore, with respect to the positive to-be-measured current Iin, the magnetoresistance change ΔR increases with the highest sensitivity (that is, the largest slope) in the range of the current amounts 0 to Iin1, decreases stepwise at the current amount Iin1, increases with low sensitivity (a small slope) in the range of the current amounts Iin1 to Iin2, decreases stepwise at the current amount Iin2, increases again with low sensitivity (a small slope) in the range of the current amounts Iin2 to Iin3, and reach the magnetic saturation at the current amount Iin3 or more. In addition, with respect to the negative to-be-measured current Iin, the magnetoresistance change ΔR decreases (increases in the negative direction) with the highest sensitivity (that is, the largest slope) in the range of the current amounts 0 to −Iin1, increases stepwise at the current amount −Iin1, decreases (increases in the negative direction) with a low sensitivity (a small slope) in the range of the current amounts −Iin1 to −Iin2, increases stepwise at the current amount −Iin2, decreases (increases in the negative direction) with low sensitivity (a small slope) again in the range of the current amounts −Iin2 to −Iin3, and reaches the magnetic saturation at the current amount −Iin3 or less.

Note that, the positive and negative of the behavior of the magnetoresistance change ΔR (that is, the output voltage Vout) of the (b) bipolar symmetry described above can be inverted (ΔR(Iin)->−ΔR(Iin)) by replacing the magnetoresistance elements 51 of types I₊, II₋, III₋ with the magnetoresistance elements 51 of types I₋, II₊, III₊, respectively.

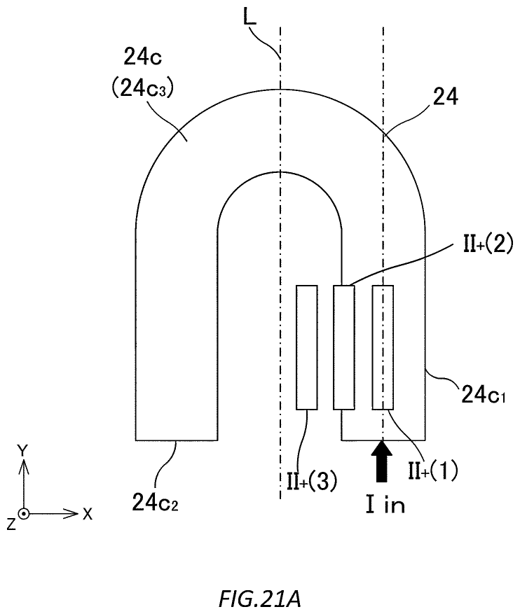

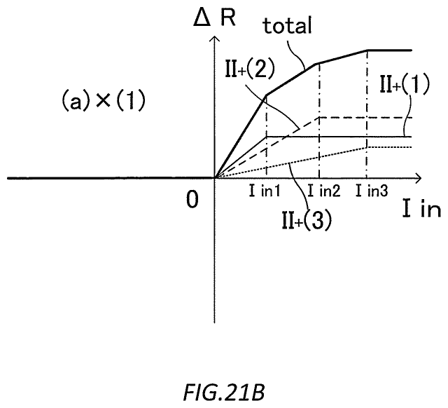

FIG. 21A illustrates the type and block arrangement of the magnetoresistance elements exhibiting the (a) unipolar and (1) logarithmic increase property. In the present example, three blocks in which the magnetoresistance elements 51 of types II₊(1) to II₊(3) are each disposed are arrayed on the top surface of the substrate 61 in the X axis direction. The magnetoresistance elements 51 of type II₊(1) to II₊(3), to which the bias magnetic fields equal to each other are each applied, have the magnetoresistances that vary with respect to the positive current amount Iin and reach the magnetic saturation at the current amounts Iin1, Iin2, Iin3 (Iin1<Iin2<Iin3) or more. The block of the magnetoresistance elements 51 of type II₊(1) is positioned on the center line of the arm 24c₁ of the conductor 24 and the magnetic field with the highest intensity generated by the to-be-measured current Iin energizing the conductor 24 is applied to those magnetoresistance elements 51; the block of the magnetoresistance elements 51 of type II₊(2) is positioned on the inner side of the arm 24c₁ and the magnetic field with a medium intensity generated by the to-be-measured current Iin is applied to those magnetoresistance elements 51; and the block of the magnetoresistance elements 51 of type II₊(3) is positioned between the arms 24c₁, 24c₂ and the magnetic field with the lowest intensity generated by the to-be-measured current Iin is applied to those magnetoresistance element 51.

FIG. 21B illustrates the property of the magnetoresistance change ΔR with respect to the energization amount Iin exhibited by each block of the magnetoresistance elements 51 in FIG. 21A and the magnetic sensors 60, 60h (each of the resistor sides R1 to R4 or R1, R2). The magnetoresistance element 51 of type II₊(1), to which the magnetic field with the highest intensity generated by the to-be-measured current Iin is applied, has the highest sensitivity with respect to the positive current amount Iin, has the magnetoresistance that varies at the zero current amount or more, and reaches the magnetic saturation at the current amount Iin or more. The magnetoresistance element 51 of type II₊(2), to which the magnetic field with a medium intensity is applied, has a medium sensitivity with respect to the positive current amount Iin, has the magnetoresistance that varies at the zero current amount or more, and reaches the magnetic saturation at the current amount Iin2 (>Iin1) or more. The magnetoresistance element 51 of type II₊(3), to which the magnetic field with the lowest intensity is applied, has the lowest sensitivity with respect to the positive current amount Iin, has the magnetoresistance that varies at the zero current amount or more, and reaches the magnetic saturation at the current amount Iin3 (>Iin2) or more.

The magnetoresistance change ΔR (total) of the magnetic sensors 60, 60h (each of the resistor sides R1 to R4 or R1, R2) is given by the linear sum of the magnetoresistances of the magnetoresistance elements 51 of three types: II₊(1) to II₊(3). Therefore, with respect to the positive to-be-measured current Iin, the magnetoresistance change ΔR increases with the highest sensitivity (that is, the largest slope) in the range of the current amounts 0 to Iin1, increases with a medium sensitivity (the medium slope) in the range of the current amounts Iin1 to Iin2, increases with the lowest sensitivity (the smallest slope) in the range of the current amounts Iin2 to Iin3, and reaches the magnetic saturation at the current amount Iin3 or more. Note that the magnetoresistance change ΔR is zero with respect to the negative current amount Iin.

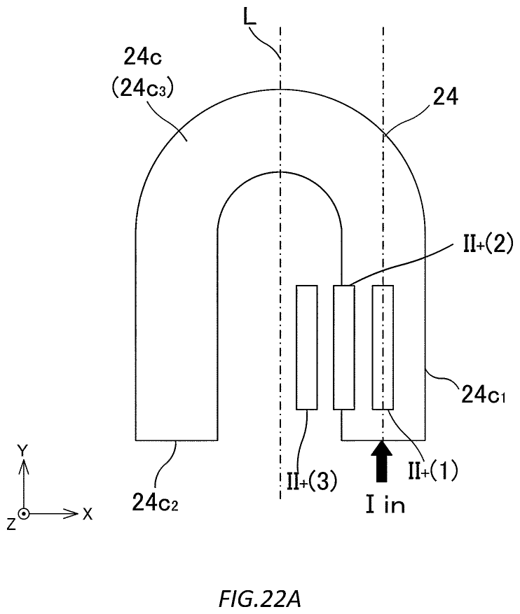

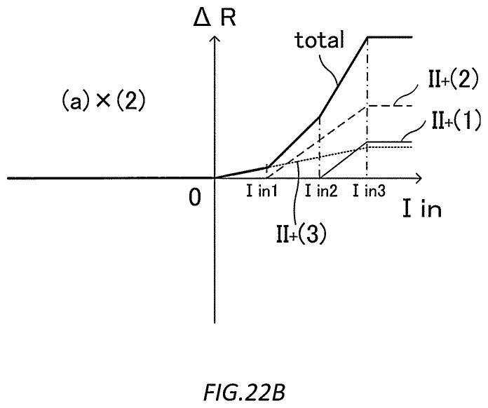

FIG. 22A illustrates the type and block arrangement of the magnetoresistance element 51 that exhibits the (a) unipolar and (2) exponential increase property. In the present example, three blocks in which the magnetoresistance elements 51 of types II₊(1) to II₊(3) are each disposed are arrayed on the top surface of the substrate 61 in the X axis direction. The block of the magnetoresistance elements 51 of type II₊(1) is positioned on the center line of the arm 24c₁ and the magnetic field with the highest intensity generated by the to-be-measured current Iin is applied to those magnetoresistance elements 51. The magnetoresistance of the magnetoresistance element 51 of type II₊(1), to which the strong bias magnetic field is applied, varies at the current amount Iin2 or more and reaches the magnetic saturation at the current amount Iin3 or more. The block of the magnetoresistance elements 51 of type II₊(2) is positioned on the inner side of the arm 24c₁ and the magnetic field with a medium intensity generated by the to-be-measured current Iin is applied to those magnetoresistance elements 51. The magnetoresistance of the magnetoresistance element 51 of type II₊(2), to which the medium bias magnetic field is applied, varies at the current amount Iin1 (<Iin2) or more and reaches the magnetic saturation at the current amount Iin3 or more. The block of the magnetoresistance elements 51 of type II₊(3) is positioned between the arms 24c₁, 24c₂ of the conductor 24 and the magnetic field with the lowest intensity generated by the to-be-measured current Iin is applied to those magnetoresistance elements 51. The magnetoresistance of the magnetoresistance element 51 of type II₊(3), to which the weak bias magnetic field is applied, varies with respect to the current amount Iin that is zero or more, and reaches the magnetic saturation at the current amount Iin3 or more.

FIG. 22B illustrates the property of the magnetoresistance change ΔR with respect to the energization amount Iin, exhibited by each block of the magnetoresistance elements 51 and the magnetic sensors 60, 60h (each of the resistor sides R1 to R4 or R1, R2) in FIG. 22A. The magnetoresistance element 51 of type II₊(1), to which the magnetic field with the highest intensity is applied, has the highest sensitivity with respect to the current amount Iin, has the magnetoresistance that varies at the current amount Iin2 or more, and reaches the magnetic saturation at the current amount Iin3 or more. The magnetoresistance element 51 of type II₊(2), to which the magnetic field with the medium intensity is applied, has the medium sensitivity with respect to the current amount Iin, has the magnetoresistance that varies at the current amount Iin1 (<Iin2) or more, and reaches the magnetic saturation at the current amount Iin3 or more. The magnetoresistance element 51 of type II₊(3), to which the magnetic field with the lowest intensity generated by the to-be-measured current Iin is applied, has the lowest sensitivity with respect to the current amount Iin, has the magnetoresistance that varies at the zero current amount or more, and reaches the magnetic saturation at the current amount Iin3 or more.

The magnetoresistance change ΔR (total) of the magnetic sensors 60, 60h (each of the resistor sides R1 to R4 or R1, R2) is given by the linear sum of the magnetoresistances of the magnetoresistance elements 51 of three types: II₊(1) to II₊(3). Therefore, with respect to the positive to-be-measured current Iin, the magnetoresistance change ΔR increases with the lowest sensitivity (that is, the smallest slope) in the range of the current amounts 0 to Iin1, increases with the medium sensitivity (the medium slope) in the range of the current amounts Iin1 to Iin2, increases with the highest sensitivity (the largest slope) in the range of the current amounts Iin2 to Iin3, and reaches the magnetic saturation at the current amount Iin3 or more. Note that the magnetoresistance change ΔR is zero with respect to the negative current amount Iin.

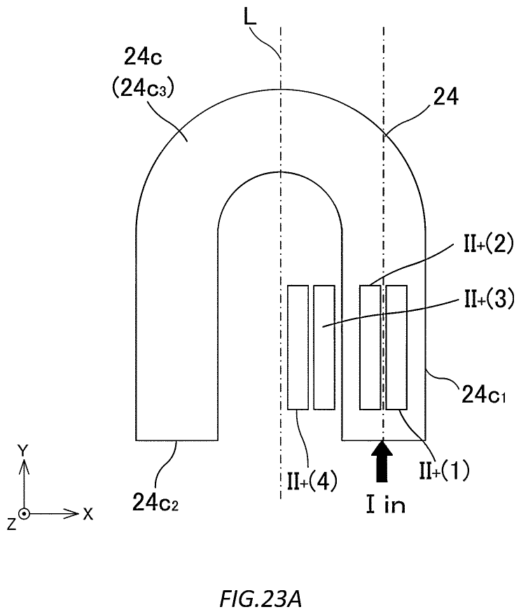

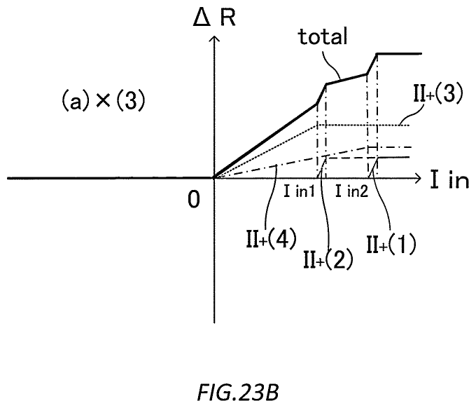

FIG. 23A illustrates the type and block arrangement of the magnetoresistance element 51 exhibiting the (a) unipolar and (3) monotonic increase property. In the present example, four blocks in which the magnetoresistance elements 51 of types II₊(1) to II₊(4) are each disposed are arrayed on the top surface of the substrate 61 in the X axis direction. The block of the magnetoresistance elements 51 of types II₊(1), II₊(2) is positioned on the arm 24c₁, and the magnetic field with approximately the highest intensity generated by the to-be-measured current Iin is applied to those magnetoresistance elements 51. The magnetoresistances of the magnetoresistance elements 51 of types II₊(1), II₊(2), to which the strong bias magnetic field and the medium bias magnetic field are applied, increase approximately stepwise at the current amounts Iin2, Iin1 (<Iin2), respectively. The blocks of the magnetoresistance elements 51 of types II₊(3), II₊(4) are positioned on the side of the arm 24c₁ and the side of the reference axis L, respectively, between the arms 24c₁, 24c₂ of the conductor 24 and the magnetic field with a medium intensity and the lowest intensity generated by the to-be-measured current Iin are applied to those magnetoresistance elements 51, respectively. The magnetoresistances of the magnetoresistance elements 51 of type II₊(3), II₊(4), to which the weak bias magnetic field is applied, linearly vary with respect to the current amount Iin that is zero or more, and reaches the magnetic saturation at the current amounts Iin1, Iin2 or more, respectively.

FIG. 23B illustrates the property of the magnetoresistance change ΔR with respect to the energization amount Iin exhibited by each block of the magnetoresistance elements 51 in FIG. 23A and the magnetic sensors 60, 60h (each of the resistor sides R1 to R4 or R1, R2). The magnetoresistance elements 51 of types II₊(1), II₊(2), to which the magnetic field with the highest intensity is applied, have the highest sensitivity with respect to the current amount Iin and have the magnetoresistances that increase approximately stepwise at the current amounts Iin2, Iin1 (<Iin2) or more, respectively, to reach the magnetic saturation. The magnetoresistance elements 51 of types II₊(3), II₊(4), to which the magnetic fields with the medium intensity and the lowest intensity generated by the to-be-measured current Iin are applied, respectively, have a low sensitivity and the lowest sensitivity with respect to the current amount Iin, have the magnetoresistances that vary at the zero current amount or more, and reach the magnetic saturation at the current amounts Iin1, Iin2 (>Iin1) or more, respectively.

The magnetoresistance change ΔR (total) of the magnetic sensors 60, 60h (each of the resistor sides R1 to R4 or R1, R2) is given by the linear sum of the magnetoresistances of the magnetoresistance elements 51 of four types: II₊(1) to II₊(4). Therefore, to the positive to-be-measured current Iin, the magnetoresistance change ΔR increases with high sensitivity (that is, a large slope) in the range of the current amounts 0 to Iin1, increases approximately stepwise at the current amount Iin1, increases with low sensitivity (a small slope) in the range of the current amounts Iin1 to Iin2, and increases approximately stepwise at the current amount Iin2 to reach the magnetic saturation. Note that the magnetoresistance change ΔR is zero with respect to the negative current amount Iin.

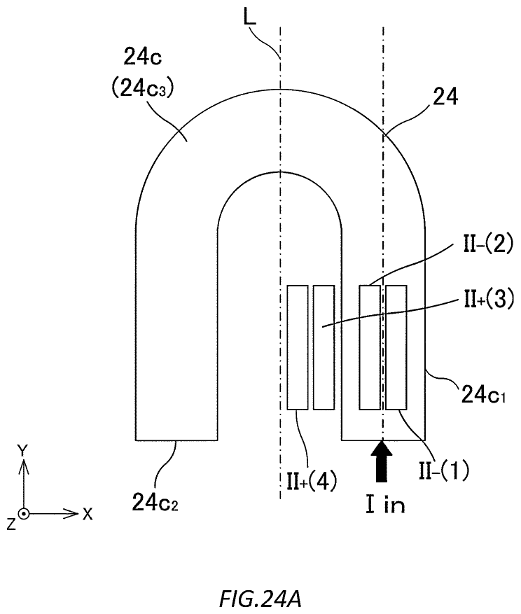

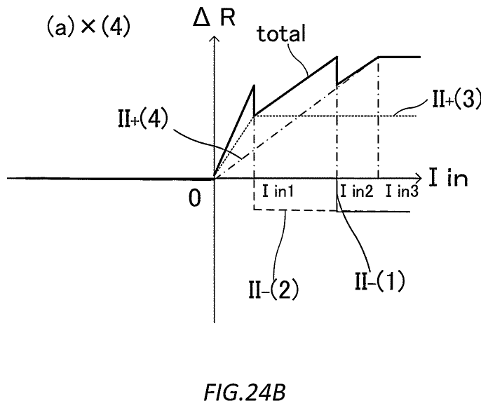

FIG. 24A illustrates the type and block arrangement of the magnetoresistance element 51 exhibiting the (a) unipolar and (4) arbitrary increase property. In the present example, four blocks in which the magnetoresistance elements 51 of types II₋(1), II₋(2), II₋(3), II₋(4) are each disposed are arrayed on the top surface of the substrate 61 in the X axis direction. The block of the magnetoresistance elements 51 of types II₋(1), II₋(2) is positioned on the arm 24c₁, and the magnetic field with an approximately highest intensity generated by the to-be-measured current Iin is applied to those magnetoresistance elements 51. The magnetoresistances of the magnetoresistance elements 51 of types II₋(1), II₋(2), to which the strong bias magnetic field and the medium bias magnetic field are applied, decrease (increase in the negative direction) stepwise at the current amounts Iin2, Iin1 (<Iin2), respectively. The blocks of the magnetoresistance elements 51 of types II₊(3), II₊(4) are positioned on the side of the arm 24c₁ and the side of the reference axis L, respectively, between the arms 24c₁, 24c₂ of the conductor 24 and the magnetic field with a medium intensity and the lowest intensity generated by the to-be-measured current Iin are applied to those magnetoresistance elements 51, respectively. The magnetoresistances of the magnetoresistance elements 51 of type II₊(3), II₊(4), to which the weak bias magnetic field is applied, linearly vary with respect to the current amount Iin that is zero or more, and reach the magnetic saturation at the current amounts Iin1, Iin3 (>Iin2>Iin1) or more, respectively.

FIG. 24B illustrates the property of the magnetoresistance change ΔR with respect to the energization amount Iin exhibited by each block of the magnetoresistance elements 51 in FIG. 24A and the magnetic sensors 60, 60h (each of the resistor sides R1 to R4 or R1, R2). The magnetoresistance elements 51 of types II₋(1), II₋(2), to which the magnetic field with the highest intensity is applied, have the highest sensitivity with respect to the current amount Iin and have the magnetoresistances that decrease (increase in the negative direction) stepwise at the current amounts Iin2, Iin1 (<Iin2) or more, respectively, to reach the magnetic saturation. The magnetoresistance elements 51 of types II₊(3), II₊(4), to which the magnetic fields with the medium intensity and the lowest intensity generated by the to-be-measured current Iin are applied, respectively, have low sensitivity and the lowest sensitivity with respect to the current amount Iin, have the magnetoresistances that vary at the zero current amount or more, and reach the magnetic saturation at the current amount Iin1, Iin3 (>Iin1) or more, respectively.

The magnetoresistance change ΔR (total) of the magnetic sensors 60, 60h (each of the resistor sides R1 to R4 or R1, R2) is given by the linear sum of the magnetoresistances of the magnetoresistance elements 51 of four types: II₋(1), II₋(2), II₊(3), II₊(4). Therefore, with respect to the positive to-be-measured current Iin, the magnetoresistance change ΔR increases with the highest sensitivity (that is, the largest slope) in the range of the current amounts 0 to Iin1, decreases stepwise at the current amount Iin1, increases with low sensitivity (a small slope) in the range of the current amounts Iin1 to Iin2, decreases stepwise at the current amount Iin2, increases again with a low sensitivity (a small slope) in the range of the current amounts Iin2 to Iin3, and reaches the magnetic saturation at the current amount Iin3 or more. Note that the magnetoresistance change ΔR is zero with respect to the negative current amount Iin.

Note that the positive and negative of the behavior of the magnetoresistance change ΔR (that is, the output voltage Vout) of the (a) unipolar property described above can be inverted (ΔR(Iin)->−ΔR(Iin)) by replacing the magnetoresistance elements 51 of types II₋, II₊ with the magnetoresistance elements 51 of types II₊, II₋, respectively.

Note that the magnetoresistance change ΔR (that is, the output voltage Vout) showing the (a) unipolar property with respect to the negative current amount can be reproduced (ΔR(Iin)->−ΔR (−Iin)) by replacing the magnetoresistance element 51 of type II₊ (or type II₋) described above with the magnetoresistance element 51 of type III₊ (or type III₋) to which the bias magnetic field is similarly applied for use.

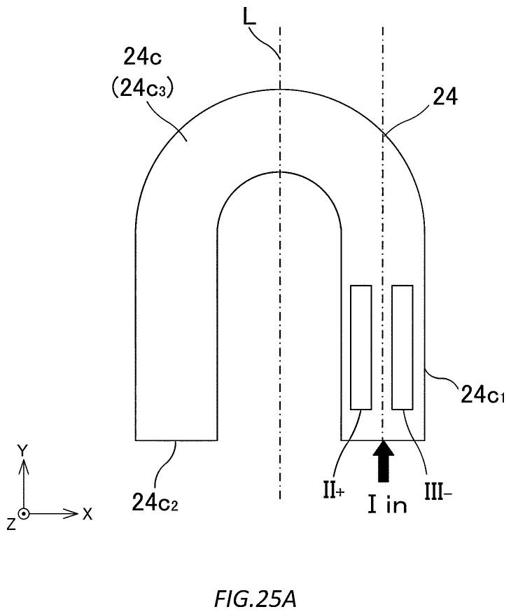

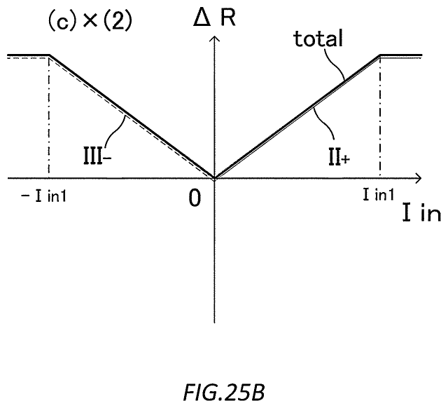

FIG. 25A illustrates the type and block arrangement of the magnetoresistance element 51 exhibiting the (c) bipolar asymmetry and (3) monotonic increase property. In the present example, two blocks in which the magnetoresistance elements 51 with type II₊, III₋ are each disposed are arrayed on the top surface of the substrate 61. The block of the magnetoresistance elements 51 of type II₊ is positioned on the arm 24c₁, and the magnetic field with approximately the highest intensity generated by the to-be-measured current Iin is applied to those magnetoresistance elements 51. The magnetoresistance of the magnetoresistance element 51 of type II₊, to which the weak bias magnetic field is applied, varies with respect to the current amount Iin that is zero or more, and reaches the magnetic saturation at the current amount Iin or more. The block of the magnetoresistance elements 51 of type III₋ is positioned on the arm 24c₁ and the magnetic field with approximately the highest intensity generated by the to-be-measured current Iin is applied to those magnetoresistance elements 51 in the same manner way it is applied to the magnetoresistance element 51 of type II₊. The magnetoresistance of the magnetoresistance element 51 of type III₋, to which the weak bias magnetic field is applied, varies with respect to the current amount Iin that is zero or less, and reaches the magnetic saturation at the current amount −Iin1 or less.

FIG. 25B illustrates the property of the magnetoresistance change ΔR with respect to the energization amount Iin exhibited by each block of the magnetoresistance elements 51 in FIG. 25A and the magnetic sensors 60, 60h (each of the resistor sides R1 to R4 or R1, R2). The magnetoresistance element 51 of type II₊, to which the magnetic field with the highest intensity generated by the to-be-measured current Iin is applied, has a high sensitivity with respect to the current amount Iin, has the magnetoresistance that varies with respect to the positive current, and reaches the magnetic saturation at the current amount Iin1 or more. The magnetoresistance element 51 of type III₋, to which the magnetic field with the highest intensity generated by the to-be-measured current Iin is applied, has a high sensitivity with respect to the current amount Iin, has the magnetoresistance that varies with respect to the negative current, and reaches the magnetic saturation at the current amount −Iin1 or less.

The magnetoresistance change ΔR (total) of the magnetic sensors 60, 60h (each of the resistor sides R1 to R4 or R1, R2) is given by the linear sum of the magnetoresistances of the magnetoresistance elements 51 of two types: II₊, III₋. Therefore, the magnetoresistance change ΔR increases with high sensitivity (that is, a large slope) with respect to the positive to-be-measured current Iin and reaches the magnetic saturation at the current amount Iin or more. In addition, the magnetoresistance change ΔR increases with high sensitivity (that is, a large slope) with respect to the negative to-be-measured current Iin and reaches the magnetic saturation at the current amount −Iin3 or less.

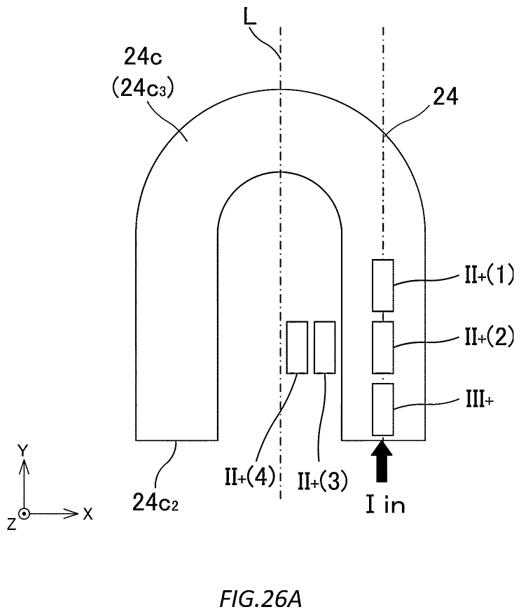

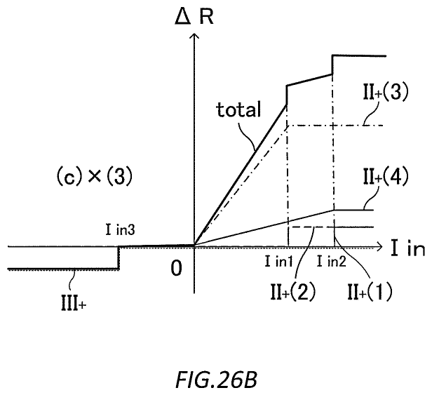

FIG. 26A illustrates the type and block arrangement of the magnetoresistance element 51 exhibiting the (c) bipolar asymmetry and (3) monotonic increase property. In the present example, five blocks in which the magnetoresistance elements 51 of types II₊(1) to II₊(4), III₊ are each disposed are arrayed on the top surface of the substrate 61. The block of the magnetoresistance elements 51 of types II₊(1), II₊(2) are positioned on the center line of the arm 24c₁ and the magnetic field with the highest intensity generated by the to-be-measured current Iin is applied to those magnetoresistance elements 51. The magnetoresistances of the magnetoresistance elements 51 of types II₊(1), II₊(2), to which the strong bias magnetic field and the medium bias magnetic field are applied, increase stepwise at the current amounts Iin2, Iin1 (<Iin2), respectively. The blocks of the magnetoresistance elements 51 of types II₊(3), II₊(4) are positioned on the side of the arm 24c₁ and the side of the reference axis L, respectively, between the arms 24c₁, 24c₂ of the conductor 24 and the magnetic field with a medium intensity and the lowest intensity generated by the to-be-measured current Iin are applied to those magnetoresistance elements 51, respectively. The magnetoresistances of the magnetoresistance elements 51 of type II₊(3), II₊(4), to which the weak bias magnetic field is applied, linearly vary with respect to the current amount Iin that is zero or more, and reaches the magnetic saturation at the current amounts Iin1, Iin2 (>Iin1) or more, respectively. The block of the magnetoresistance elements 51 of type III₊, is positioned on the center line of the arm 24c₁ and the magnetic field with the highest intensity generated by the to-be-measured current Iin is applied to those magnetoresistance elements 51. The magnetoresistance of the magnetoresistance element 51 of type III₊, to which the bias magnetic field is applied, decreases (increases in the negative direction) stepwise at the current amount −Iin3.

FIG. 26B illustrates the property of the magnetoresistance change ΔR with respect to the energization amount Iin exhibited by each block of the magnetoresistance elements 51 in FIG. 26A and the magnetic sensors 60, 60h (each of the resistor sides R1 to R4 or R1, R2). The magnetoresistance elements 51 of types II₊(1), II₊(2), to which the magnetic field with the highest intensity is applied, have the highest sensitivity with respect to the current amount Iin and have the magnetoresistances that increase stepwise at the current amounts Iin2, Iin1 (<Iin2) or more, respectively, to reach the magnetic saturation. The magnetoresistance elements 51 of types II₊(3), II₊(4), to which the magnetic fields with the medium intensity and the lowest intensity generated by the to-be-measured current Iin are applied, respectively, have low sensitivity and the lowest sensitivity with respect to the current amount Iin, have the magnetoresistances that vary at the zero current amount or more, and reach the magnetic saturation at the current amounts Iin1, Iin2 (>Iin1) or more, respectively. The magnetoresistance element 51 of type III₊, to which the magnetic field with the highest intensity is applied, has the highest sensitivity with respect to the current amount Iin, and has the magnetoresistance that decreases (increases in the negative direction) stepwise at the current amount −Iin3 or less to reach the magnetic saturation.

The magnetoresistance change ΔR (total) of the magnetic sensors 60, 60h (each of the resistor sides R1 to R4 or R1, R2) is given by the linear sum of the magnetoresistances of the magnetoresistance elements 51 of five types: II₊(1) to II₊(4), III₊. Therefore, with respect to the positive to-be-measured current Iin, the magnetoresistance change ΔR increases with the highest sensitivity (that is, the largest slope) in the range of the current amounts 0 to Iin1, increases stepwise at the current amount Iin1, increases with a low sensitivity (a small slope) in the range of the current amounts Iin1 to Iin2, and increases stepwise at the current amount Iin2 to reach the magnetic saturation. With respect to the negative to-be-measured current Iin, the magnetoresistance change ΔR is zero in the range of the current amounts 0 to −Iin1 and decreases (increases in the negative direction) stepwise at the current amount −Iin1 to reach the magnetic saturation.

Note that the positive and negative of the behavior of the magnetoresistance change ΔR (that is, the output voltage Vout) of the (c) bipolar asymmetry described above can be inverted (ΔR(Iin)->−ΔR(Iin)) by replacing the magnetoresistance elements 51 of types I₊, II₊, III₊ with the magnetoresistance elements 51 of types I₋, II₋, III₋, respectively.

Note that the magnetoresistance change ΔR (that is, the output voltage Vout) showing the (c) bipolar asymmetrical property with respect to the negative current amount can be reproduced (ΔR(Iin)->−ΔR (−Iin)) by replacing the magnetoresistance element 51 of type II₊ (or type II₋) described above with the magnetoresistance element 51 of type III₊ (or type III₋) to which the bias magnetic field is similarly applied for use.

The manufacturing method of the current sensor 110 will be described.

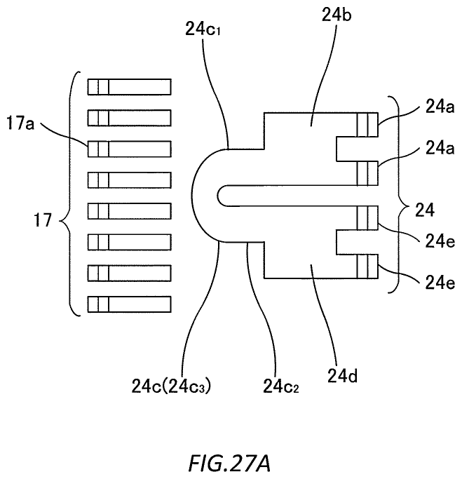

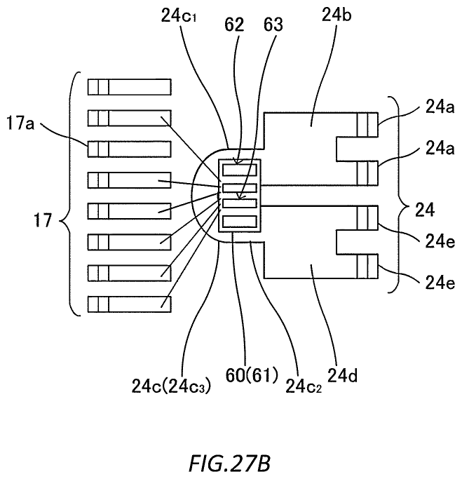

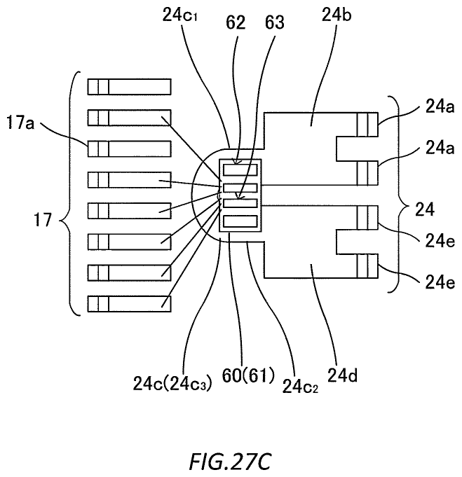

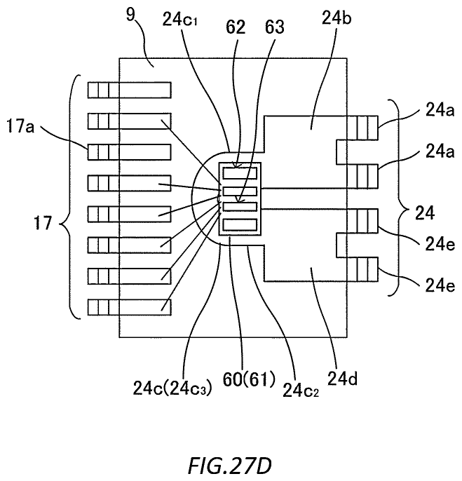

As illustrated in FIG. 27A, at first, one piece of metal board undergoes a stamping process to form the pattern of the plurality of device terminals 17 and the conductor 24. This pattern allows the plurality of device terminals 17 and the conductor 24 to be included within a rectangular-shaped frame (not shown), with their terminal portions coupled inside.

Then, the pattern undergoes a step process to provide steps in the plurality of device terminals 17 and the conductor 24. As a result, with respect to the frame and their terminal portions coupled to the frame, the inner part of the pattern is raised.

As illustrated in FIG. 27B, the magnetic sensor 60 is then installed. Herein, the two magneto-electric conversion units 62, 63 are arranged on the arms 24c₁, 24c₂ of the conductor 24, respectively.

As illustrated in FIG. 27C, the magnetic sensor 60 is then connected to the plurality of device terminals 17 through wire bonding.

As illustrated in FIG. 27D, the pattern is then molded with the frame and the terminal portions of the plurality of device terminals 17 and the conductor 24 coupled thereto remained. In this way, the package 9 is formed and the magnetic sensor 60 and the inner part of the pattern are sealed inside the package 9.

Finally, the frame exposed on the outside of the package 9 is cut off from the pattern. In this way, the plurality of device terminals 17 and the conductor 24 are separated from each other to complete the current sensor 110.

The magnetic sensors 60, 60h according to the present embodiment includes a substrate 61 installed on the conductor 24, where a plurality of blocks including first blocks 62a, 63a and second blocks 62b, 63b positioned near and far from the center line of the conductor 24, respectively, relative to each other are arranged on one surface, a plurality of magnetoresistance elements 51 disposed on the substrate 61, a part of which is disposed on the first blocks 62a, 63a and another part of which is disposed on the second blocks 62b, 63b, wherein each of the first blocks 62a, 63a and the second blocks 62b, 63b includes the first subblocks 62a₁, 63a₁, 62b₁, 63b₁ in which the magnetoresistance elements 51 having the magnetic sensing directions that are directions identical to each other, and the magnetoresistance elements 51 in the first subblock 62a₁, 63a₁ of the first blocks 62a, 63a and the magnetoresistance elements 51 in the first subblock 62b₁, 63b₁ of the second blocks 62b, 63b are connected in series to form the resistor side R1.

According to this, among the magnetoresistance elements 51 in the first subblocks 62a₁, 63a₁ of the first blocks 62a, 63a and the magnetoresistance elements 51 of the first subblocks 62b₁, 63b₁ of the second blocks 62b, 63b that have the magnetic sensing directions being the direction identical to each other and are connected in series to form the resistor side R1, the former is positioned relatively near the center line of the conductor 24 on one surface of the substrate 61 to exhibit a high sensitivity to the magnetic field generated by energizing the conductor 24 and the latter is positioned relatively far from the center line of the conductor 24 to exhibit a low sensitivity to the magnetic field generated by energizing the conductor 24, which can achieve the magnetic sensors 60, 60h having a multi-linearity to the magnetic field intensity, where, with the current amount energizing the conductor 24 being equal to or less than the amount generating the magnetic field equal to the saturation magnetic field of the magnetoresistance element 51 at the position of the first blocks 62a, 63a, the resistor side R1 exhibits a high linearity having the sum of the sensitivities of the magnetoresistance elements 51 of the first blocks 62a, 63a and the sensitivities of the magnetoresistance elements 51 of the second blocks 62b, 63b and, with the current amount being equal to or less than the amount generating the magnetic field exceeding the saturation magnetic field at the positions of the first blocks 62a, 63a and also generating the magnetic field equal to the saturation magnetic field at the positions of the second blocks 62b, 63b, the resistor side R1 exhibits a low linearity equal to the sensitivities of the magnetoresistance elements 51 of the second blocks 62b, 63b.

The current sensor 110 according to the present embodiment includes a conductor 24, magnetic sensors 60, 60h, and a package 9 that seals the conductor 24 and the magnetic sensor 60. The current sensor having multi-linearity can be constituted by using the magnetic sensors 60, 60h.

Note that the magnetic sensor 60 is described to include the two magneto-electric conversion units 62, 63, but instead it may include only one of the magneto-electric conversion units 62, 63.

Note that the magnetic field detection direction (that is, the magnetic sensing direction) of the resistor sides R1 to R8 (the magnetoresistance elements 51) included in the two magneto-electric conversion units 62, 63 of the magnetic sensor 60 may be the direction perpendicular to the top surface of the conductor 24 and one of the two magneto-electric conversion units 62, 63 may be arranged in a gap region surrounded by the curved portion 24c of the conductor 24. In this way, the magnetic sensor 60 can detect the perpendicular magnetic field (the magnetic field in the Z axis direction in FIG. 1A, in the case of the present example). In addition, the other of the two magneto-electric conversion units 62, 63 may be arranged near the outer side of one of the two arms 24c₁, 24c₂ of the conductor 24. In this way, the disturbance magnetic field can be canceled.

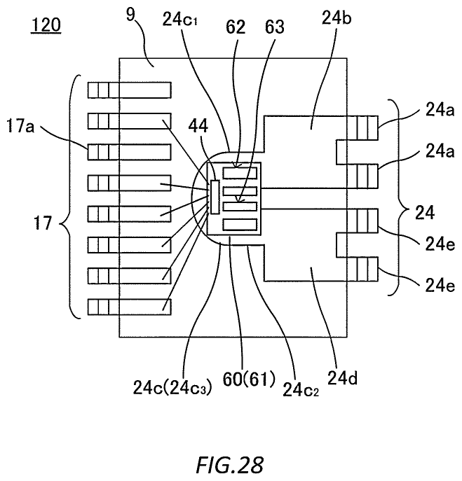

FIG. 28 illustrates the internal configuration of the current sensor 120 according to a modification example in the top view. In addition to the components included in the above-described current sensor 110, the current sensor 120 further include a signal processing circuit 44 that processes the detection signal of the magnetic sensor 60 (for example, the resistance variation of the resistor side R1 and the like) and calculates the amount of the to-be-measured current energizing the conductor 24. The signal processing circuit 44 may also incorporate a memory, a sensitivity compensation circuit, an offset compensation circuit that compensates the offset of the output, an amplification circuit that amplifies the output signal from the magnetic sensor 60, and a temperature compensation circuit that compensates the output according to the temperature. The signal processing circuit 44 is disposed on the substrate 61 of the magnetic sensor 60, has the electrode pad (not shown) on the substrate 61 as the input/output terminal of the signal processing circuit 44, and is connected to the plurality of device terminals 17 through wire bonding. In this way, the signal processing circuit 44 outputs the calculation result of the amount of the to-be-measured current energizing the conductor 24 via the plurality of device terminals 17.

While the present invention has been described with the embodiments, the technical scope of the present invention is not limited to the above-described embodiments. It is apparent to persons skilled in the art that various alterations or improvements can be made to the above-described embodiments. It is also apparent from description of the claims that the embodiments to which such modifications or improvements are made may be included in the technical scope of the present invention.

It should be noted that each process of the operations, procedures, steps, stages, and the like performed by the apparatus, system, program, and method shown in the claims, specification, or drawings can be executed in any order as long as the order is not indicated by “prior to”, “before”, or the like and as long as the output from a previous process is not used in a later process. Even if the operation flow is described using phrases such as “first” or “next” for the sake of convenience in the claims, specification, or drawings, it does not necessarily mean that the process must be performed in this order.

What is claimed is:

1. A magnetic sensor comprising:
a substrate installed on a conductor, where a plurality of blocks including a first block and a second block positioned near and far from a center line of the conductor, respectively, relative to each other in a plan view are arranged on one surface; and
a plurality of magnetoresistance elements disposed on the substrate, wherein a part of the plurality of magnetoresistance elements is disposed in the first block and another part is disposed in the second block,
wherein each of the first block and the second block includes a first subblock in which magnetoresistance elements having magnetic sensing directions that are directions identical to each other are disposed, and a magnetoresistance element in the first subblock of the first block and a magnetoresistance element in the first subblock of the second block are connected in series to form a first resistor side.

2. The magnetic sensor according to claim 1, wherein each of the first block and the second block further includes a second subblock in which magnetoresistance elements having magnetic sensing directions that are directions identical to each other and are directions opposite to those of the magnetoresistance elements in the first subblock are disposed, and
a magnetoresistance element in the second subblock of the first block and a magnetoresistance element in the second subblock of the second block are connected in series to form a second resistor side, and the first resistor side and the second resistor side are connected in series.

3. The magnetic sensor according to claim 2, wherein each of the first block and the second block further includes a third subblock in which magnetoresistance elements having magnetic sensing directions that are directions identical to each other and are directions identical to those of magnetoresistance elements in the first subblock are disposed and a fourth subblock in which magnetoresistance elements having magnetic sensing directions that are directions identical to each other and are directions opposite to those of the magnetoresistance elements in the first subblock are disposed,
a magnetoresistance element in the third subblock of the first block and a magnetoresistance element in the third subblock of the second block are connected in series to form a third resistor side, and a magnetoresistance element in the fourth subblock of the first block and a magnetoresistance element in the fourth subblock of the second block are connected in series to form a fourth resistor side, and
the third resistor side and the fourth resistor side are connected in series to each other and are connected in parallel to the first resistor side and the second resistor side to be assembled into a Wheatstone bridge circuit together with the first resistor side and the second resistor side.

4. The magnetic sensor according to claim 1, wherein the plurality of blocks further include at least one extension block that is arranged on one surface of the substrate and is spaced apart from the first block and the second block,
yet another part of the plurality of magnetoresistance elements is disposed in the at least one extension block,
the at least one extension block includes a first subblock in which magnetoresistance elements having magnetic sensing directions that are directions identical to each other and are directions identical to those of magnetoresistance elements in the first subblock of the first block are disposed, and
the first resistor side includes a magnetoresistance element in the first subblock of the extension block, which is connected in series to a magnetoresistance element in the first subblock of the first block and a magnetoresistance element in the first subblock of the second block.

5. The magnetic sensor according to claim 4, wherein each of the first block, the second block, and the at least one extension block further includes a second subblock in which magnetoresistance elements having magnetic sensing directions that are directions identical to each other and are directions opposite to those of magnetoresistance elements in the first subblock are disposed, and
a magnetoresistance element in the second subblock of the first block, a magnetoresistance element in the second subblock of the second block, and a magnetoresistance element in the second subblock of the at least one extension block are connected in series to form a second resistor side and the first resistor side and the second resistor side are connected in series.

6. The magnetic sensor according to claim 5, wherein each of the first block, the second block, and the at least one extension block further includes a third subblock in which magnetoresistance elements having magnetic sensing directions that are directions identical to each other and are directions identical to those of magnetoresistance elements in the first subblock are disposed and a fourth subblock in which magnetoresistance elements having magnetic sensing directions that are directions identical to each other and are directions opposite to those of magnetoresistance elements in the first subblock are disposed,
a magnetoresistance element in the third subblock of the first block, a magnetoresistance element in the third subblock of the second block, and a magnetoresistance element in the third subblock of the at least one extension block are connected in series to form a third resistor side, and a magnetoresistance element in the fourth subblock of the first block, a magnetoresistance element in the fourth subblock of the second block, and a magnetoresistance element in the fourth subblock of the at least one extension block are connected in series to form a fourth resistor side, and
the third resistor side and the fourth resistor side are connected in series to each other and are connected in parallel to the first resistor side and the second resistor side, to be assembled into a Wheatstone bridge circuit together with the first resistor side and the second resistor side.

7. The magnetic sensor according to claim 1, wherein at least a part of the first block is positioned on the conductor in a plan view, and
at least a part of the second block is positioned outside the conductor in a plan view.

8. The magnetic sensor according to claim 1, wherein at least a part of the first block is positioned on the conductor in a plan view, and
the second block is positioned outside the conductor in a plan view.

9. The magnetic sensor according to claim 1, wherein the first block is positioned on the conductor in a plan view, and
at least a part of the second block is positioned on the conductor in a plan view.

10. The magnetic sensor according to claim 1, wherein the first block and the second block are arrayed in a direction intersecting an energization direction of the conductor.

11. The magnetic sensor according to claim 1, wherein the plurality of magnetoresistance elements are tunnel magnetoresistance elements (TMR) or giant magnetoresistance elements (GMR).

12. The magnetic sensor according to claim 10, wherein at least one magnetoresistance element among the plurality of magnetoresistance elements has a free layer to which a bias magnetic field is applied.

13. The magnetic sensor according to claim 12, wherein the bias magnetic field is applied by any of magnetic coupling of an antiferromagnetic material to the free layer, magnetic coupling through synthetic ferrimagnetic structure, which is a tri-layer structure of a ferromagnetic material/a non-magnetic material/a ferromagnetic material, to the free layer, which is a ferromagnetic material, arrangement of a magnet near the free layer, and arrangement of coil wiring near the free layer.

14. The magnetic sensor according to claim 12, wherein magnetoresistance elements disposed in at least two blocks among the plurality of blocks have free layers to which the bias magnetic field is applied,
magnetoresistance elements disposed in at least two blocks among the plurality of blocks have free layers to which the bias magnetic field is not applied, and
among the plurality of blocks, a block in which a magnetoresistance element having a free layer to which the bias magnetic field is not applied is disposed is arranged far from the conductor relative to a block in which a magnetoresistance element having a free layer to which the bias magnetic field is applied is disposed.

15. The magnetic sensor according to claim 1, wherein the conductor has a U-shape, a right-angle U-shape, a n-shape, or a V-shape including two arms that are symmetrical or approximately symmetrical with respect to a reference line, and
the first block and the second block are each arranged on one of the two arms in a symmetrical manner with respect to the reference line.

16. The magnetic sensor according to claim 7, wherein the conductor has a U-shape, a right-angle U-shape, a n-shape, or a V-shape including two arms that are symmetrical or approximately symmetrical with respect to a reference line,
the first block and the second block are each arranged on one of the two arms in a symmetrical manner with respect to the reference line, and
the second block is arranged on a side of the reference line with respect to the first block.

17. The magnetic sensor according to claim 1, further comprising a signal processing circuit that is disposed on the substrate and processes a detection signal of a resistance variation of the first resistor side.

18. A current sensor comprising:
the magnetic sensor according to claim 1; and
the conductor through which a to-be-measured current flows.

19. The current sensor according to claim 18, wherein the conductor includes a first arm, a second arm spaced apart from the first arm in a width direction, and a joining portion that joins the first arm and the second arm, and
the first arm and the second arm extend on a same side as the joining portion.
